(19) United States
(12) Patent Application Publication
(10) Pub. No.: US 2025/0234506 A1
(43) Pub. Date: Jul. 17, 2025

(54) SEMICONDUCTOR DEVICES

(71) Applicant: Samsung Electronics Co., Ltd., Suwon-si (KR)

(72) Inventors: Donghyung Kim, Suwon-si (KR); Jongmin Kim, Suwon-si (KR); Kiseok Lee, Suwon-si (KR); Hyunjin Lee, Suwon-si (KR); Yongkwan Kim, Suwon-si (KR); Huijung Kim, Suwon-si (KR)

(21) Appl. No.: 18/754,587

(22) Filed: Jun. 26, 2024

(30) Foreign Application Priority Data
Jan. 17, 2024 (KR) 10-2024-0007130

(51) Int. Cl. H10B 12/00

(52) U.S. Cl. CPC H10B 12/315; H10B 12/0335; H10B 12/482

(57) ABSTRACT

A semiconductor device includes an active pattern on a substrate, the active pattern including a central portion, and a first end portion and a second end portion at opposite ends of the central portion, an insulation pattern, a first pad pattern and a second pad pattern respectively on the first and second end portions of the active pattern, a bit line structure on the first pad pattern, and a contact plug structure on the second pad pattern. An area of an upper surface of the first pad pattern is greater than an area of an upper surface of the first end portion of the active pattern directly contacting the first pad pattern, and an area of an upper surface of the second pad pattern is greater than an area of an upper surface of the second end portion of the active pattern directly contacting the second pad pattern.

### CROSS-REFERENCE TO RELATED APPLICATION

This application claims priority under 35 U.S.C. § 119 to Korean Patent Application No. 10-2024-0007130 filed on Jan. 17, 2024 in the Korean Intellectual Property Office, the disclosure of which is hereby incorporated by reference in its entirety.

### TECHNICAL FIELD

Example embodiments relate to a semiconductor device, more particularly, a DRAM device.

### BACKGROUND

The DRAM device may include a gate structure extending in a first direction through a central portion of an active pattern, a bit line extending in a second direction on a first end portion of the active pattern, a contact plug structure on a second end portion of the active pattern and a capacitor on the contact plug structure.

As the DRAM device becomes highly integrated, a contact area between the bit line and the active pattern and a contact area between the contact plug structure and the active pattern may decrease, which may result in a poor electrical connection therebetween.

### SUMMARY

Example embodiments provide a semiconductor device having improved characteristics.

According to example embodiments, there is provided a semiconductor device. The semiconductor device may include an active pattern on a substrate, the active pattern including a central portion, and a first end portion and a second end portion at opposite ends of the central portion, an insulation pattern that extends into a portion of the first end portion of the active pattern and extends into a portion of the second end portion of the active pattern, a first pad pattern and a second pad pattern respectively on the first and second end portions of the active pattern, a gate structure that extends into the central portion of the active pattern, a bit line structure on the first pad pattern, a contact plug structure on the second pad pattern, and a capacitor on the contact plug structure. An area of an upper surface of the first pad pattern is greater than an area of an upper surface of the first end portion of the active pattern directly contacting the first pad pattern, and an area of an upper surface of the second pad pattern is greater than an area of an upper surface of the second end portion of the active pattern directly contacting the second pad pattern.

According to example embodiments, there is provided a semiconductor device. The semiconductor device may include active patterns on a substrate, the active patterns including respective central portions, respective first end portions, and respective second end portions, the respective first end portions and the respective second end portions at opposite ends of the central portion. The active patterns spaced apart from each other in a first direction and in a second direction. The first and second directions are substantially parallel to an upper surface of the substrate and are substantially perpendicular to each other. The semiconductor device includes insulation patterns that extend into respective portions of ones of the respective first end portions of first active patterns of the active patterns, and respective portions of ones of the respective second end portions of second active patterns of the active patterns, respective ones of the first and second active patterns are adjacent to each other in the first direction, first pad patterns respectively on the respective first end portions of the active patterns, second pad patterns respectively on the respective second end portions of the active patterns, gate structures that each extend into the respective central portions of the active patterns in the first direction, the gate structures are spaced apart from each other in the second direction, bit line structures that extend in the second direction on the first pad patterns, the bit line structures are spaced apart from each other in the first direction, contact plug structures respectively on the second pad patterns, and capacitors respectively on the contact plug structures.

According to example embodiments, there is provided a semiconductor device. The semiconductor device may include an active pattern on a substrate, the active pattern including a central portion, and a first end portion and a second end portion that are at opposite ends of the central portion, an insulation pattern that extends into a portion of the first end portion of the active pattern and a portion of the second end portion of the active pattern, a first pad pattern and a second pad pattern respectively on the first and second end portions of the active pattern, a gate structure that extends into the central portion of the active pattern, a bit line structure on the first pad pattern, a contact plug structure on the second pad pattern, and a capacitor on the contact plug structure. An uppermost surface of the insulation pattern with respect to the substrate and an upper surface of the second pad pattern with respect to the substrate are substantially coplanar.

In the semiconductor device according to example embodiments, the first pad pattern and the second pad pattern may be on the first and second end portions of the active pattern, respectively. The bit line may be electrically connected to the first end portion of the active pattern through the first pad pattern, and the contact plug structure may be electrically connected to the second end portion of the active pattern through the second pad pattern. Compared to the case where the bit line and the contact plug structure are in direct contact with the first and second end portions of the active pattern, respectively, electrical connection therebetween may be improved.

### BRIEF DESCRIPTION OF THE DRAWINGS

FIGS. 1 to 3 are a plan view and cross-sectional views illustrating a semiconductor device according to example embodiments.

FIGS. 4 to 35 are plan views and cross-sectional views illustrating a method of manufacturing a semiconductor device according to example embodiments.

FIG. 36 is a cross-sectional view illustrating a semiconductor device according to example embodiments.

FIGS. 37 to 40 are plan views and cross-sectional views illustrating a method of manufacturing a semiconductor device illustrated with reference to FIG. 36.

FIG. 41 is a cross-sectional view illustrating a semiconductor device according to example embodiments.

FIGS. 42 to 46 are plan views and cross-sectional views illustrating a method of manufacturing a semiconductor device illustrated with reference to FIG. 41.

FIGS. 47 to 55 are plan views and cross-sectional views illustrating a method of manufacturing a semiconductor device according to example embodiments.

FIGS. 56 to 66 are plan views and cross-sectional views illustrating a method of manufacturing a semiconductor device according to example embodiments.

FIGS. 67 and 68 are cross-sectional views illustrating a semiconductor device according to example embodiments.

FIGS. 69 and 70 are cross-sectional views illustrating a method of manufacturing a semiconductor device illustrated with reference to FIGS. 67 and 68.

FIGS. 71 and 72 are a plan view and a cross-sectional view illustrating a semiconductor device according to example embodiments.

FIG. 73 is a cross-sectional view illustrating a semiconductor device according to example embodiments.

FIG. 74 is a cross-sectional view illustrating a method of manufacturing a semiconductor device illustrated with reference to FIG. 73.

### DETAILED DESCRIPTION

The above and other aspects and features of a semiconductor device, a method of manufacturing the same, and an electronic system including the same in accordance with example embodiments will become readily understood from detail descriptions that follow, with reference to the accompanying drawings. It will be understood that, although the terms “first,” “second,” and/or “third” may be used herein to describe various materials, levels (layers), regions, pads, electrodes, patterns, structures or processes should not be limited by these terms. These terms are only used to distinguish one material, level (layer), region, pad, electrode, pattern, structure or process from another material, level (layer), region, pad, electrode, pattern, structure or process. Thus, a first material, level (layer), region, pad, electrode, pattern, structure or process discussed below could be termed a second or third material, level (layer), region, pad, electrode, pattern, structure or process without departing from the teachings of inventive concepts.

Hereinafter, two directions among horizontal directions that are substantially parallel to an upper surface of a substrate, which may be substantially orthogonal to each other and/or intersect one another, may be referred as first and second directions D1 and D2, respectively, and a direction among the horizontal directions, which may have an acute angle with respect to the second direction D2 and an obtuse angle with respect to the first direction D1 may be referred to as a third direction D3. Additionally, a direction substantially perpendicular to the upper surface of the substrate may be referred to as a vertical direction. Each of the first to third directions D1, D2 and D3 and the vertical direction may represent not only a direction shown in the drawing, but also a reverse direction to the direction that is shown.

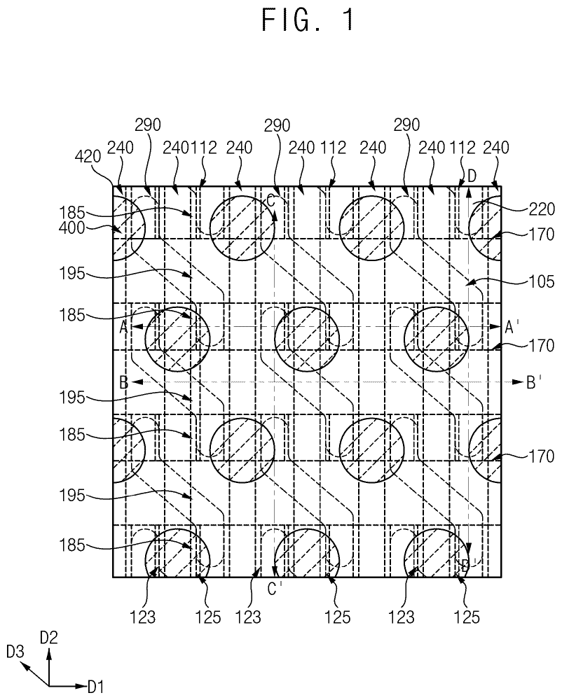

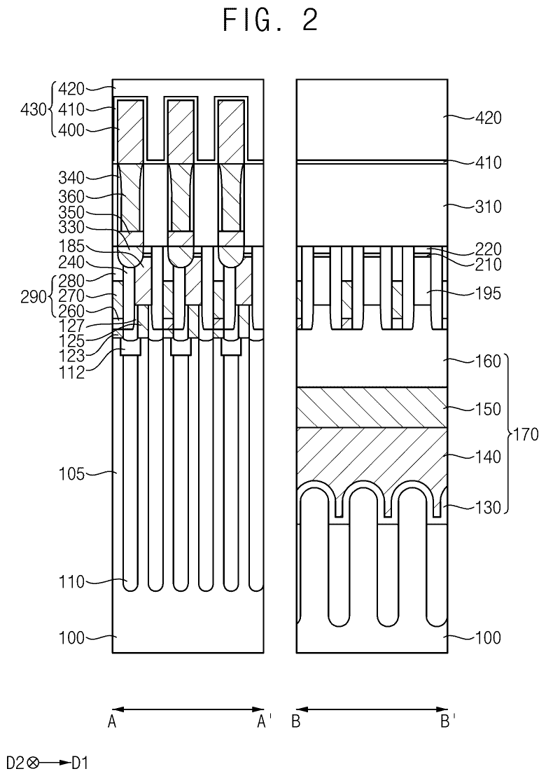

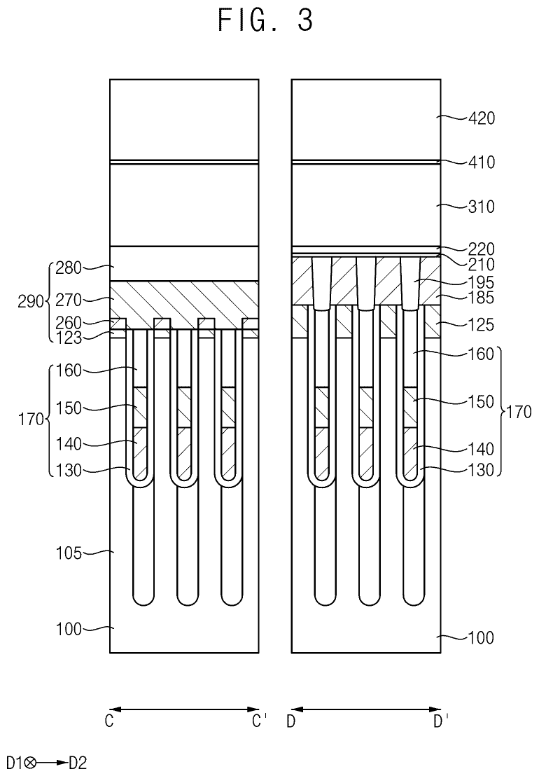

FIGS. 1 to 3 are a plan view and cross-sectional views illustrating a semiconductor device according to example embodiments. Specifically, FIG. 1 is the plan view, FIG. 2, includes cross-sectional views taken along lines A-A′ and B-B′ of FIG. 1, and FIG. 3 includes cross-sectional views taken along lines C-C′ and D-D′ of FIG. 1.

Referring to FIGS. 1 to 3, the semiconductor device may include an active pattern 105, a first insulation pattern 112, a first pad pattern 123, a second pad pattern 125, a gate structure 170, a first bit line structure, a first contact plug 185, a contact plug structure and a capacitor 430 on a substrate 100.

The semiconductor device may further include an isolation pattern 110, a first fence pattern 127, a second fence pattern 195, a buffer layer structure, a second mold layer 310, a second spacer 340 and an etch stop layer.

The substrate 100 may include silicon, germanium, silicon-germanium or a III-V group compound such as GaP, GaAs, GaSb, etc. In some embodiments, the substrate 100 may be a silicon-on-insulator (SOI) substrate or a germanium-on-insulator (GOI) substrate.

The active pattern 105 may be defined on the substrate 100, and a sidewall of the active pattern 105 may be on, covered by, or overlapped by the isolation pattern 110.

The active pattern 105 may include a central portion, a first end portion and a second end portion. The central portion of the active pattern 105 may extend in the third direction D3 to a certain length. The first and second end portions may be formed at opposite ends in the third direction D3 of the central portion of the active pattern 105, respectively. The first and second end portions may extend in the second direction D2 away from the central portion to a certain length, respectively.

A plurality of active patterns 105 may be spaced apart from each other in the first and second directions D1 and D2 to define an active pattern array. A plurality of active patterns 105 arranged along the first direction D1 of the active pattern array may define an active pattern row. A plurality of active pattern rows may be spaced apart from each other in the second direction D2. A plurality of active patterns 105 arranged along the second direction D2 of the active pattern array may define an active pattern column. A plurality of active pattern columns may be spaced apart from each other in the first direction D1.

In example embodiments, the active patterns 105 of the active pattern row may be aligned with each other in the first direction D1. Specifically, the first end portions of the active patterns 105 of the active pattern row may be arranged on a straight line extending in the first direction D1, and the second end portions of the active patterns 105 of the active pattern row may be arranged on a straight line extending in the first direction D1.

In example embodiments, the active patterns 105 of the active pattern column may be aligned with each other in the second direction D2. Specifically, the first end portions of the active patterns 105 of the active pattern column may be arranged on a straight line extending in the second direction D2, and the second end portions of the active patterns 105 of the active pattern column may be arranged on a straight line extending in the second direction D2.

The first end portion of the active pattern 105 of a first active pattern row of the active pattern rows may be disposed between the second end portions of the active patterns 105 adjacent to each other in the first direction D1 of a second active pattern row of the active pattern rows. The first and second active pattern rows may be adjacent to each other in the second direction D2.

The active pattern 105 may include substantially the same material as the substrate 100, and the isolation pattern 110 may include an oxide, e.g., silicon oxide.

A plurality of first insulation patterns 112 may be spaced apart from each other in the first and second directions D1 and D2. Some of the first insulation patterns 112 may extend through an upper portion of a first end in the first direction D1 of the first end portion of the active pattern 105 adjacent to the central portion of the active pattern 105, and others of the first insulation patterns 112 may extend through an upper portion of a second end in the first direction D1 of the second end portion of the active pattern 105 adjacent to the central portion of the active pattern 105.

In some embodiments, the first insulation pattern 112 may have a shape of a line extending in the second direction D2 in a plan view, and a plurality of first insulation patterns 112 may be spaced apart from each other in the first direction D1. Specifically, the first insulation pattern 112 may extend in the second direction D2 through upper portions of the central portions of the active patterns 105 of the active pattern column. The first insulation pattern may also extend through the upper portion of the first end in the first direction D1 of the first end portion of the active pattern 105 adjacent to the central portion of the active pattern 105 and the second end in the first direction D1 of the second end portion of the active pattern 105 adjacent to the central portion of the active pattern 105.

An area of an upper surface of the first end portion of the active pattern 105 may be reduced by an upper surface of the first end through which the first insulation pattern 112 may pass. Also, an area of an upper surface of the second end portion of the active pattern 105 may be reduced by an upper surface of the second end through which the first insulation pattern 112 may pass.

In example embodiments, the first insulation pattern 112 may include, for example, a low dielectric material, such as silicon oxide, silicon oxycarbide, etc.

The first pad pattern 123 and the second pad pattern 125 may be formed on the first and second end portions of the active pattern 105, respectively. Accordingly, corresponding to the first and second end portions of the active patterns 105 which are alternately and repeatedly arranged in the first direction D1, the first and second pad patterns 123 and 125 may also be alternately and repeatedly arranged in the first direction D1.

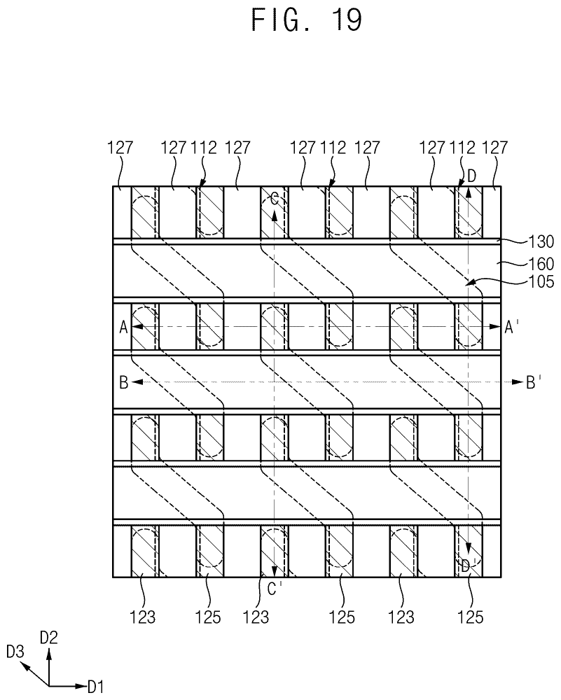

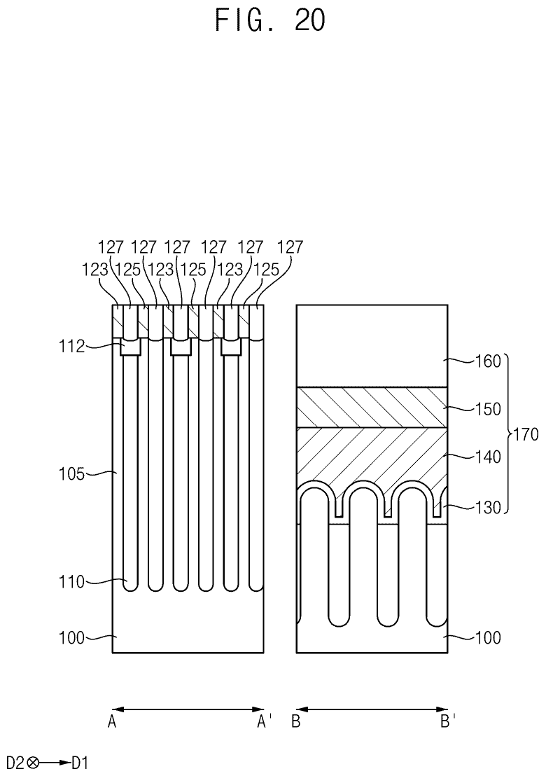

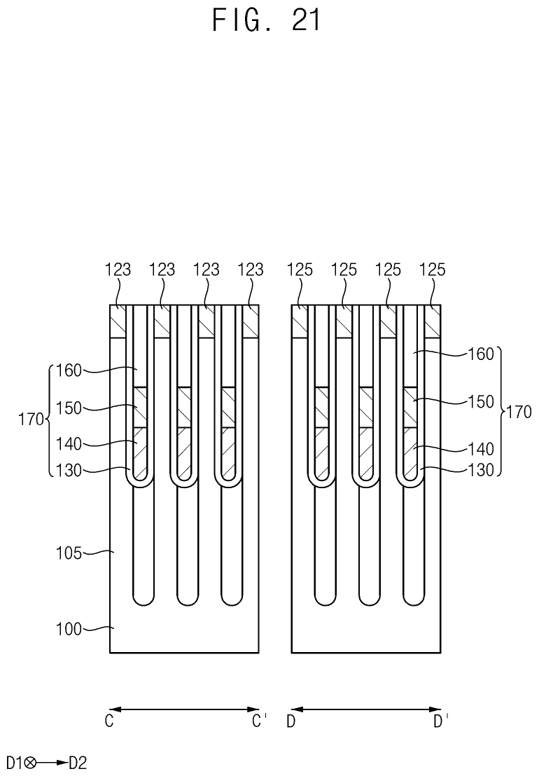

Referring to FIGS. 19 to 21 together with FIGS. 1 to 3, an area of an upper surface of the first pad pattern 123 may be greater than an area of an upper surface of the first end portion of the active pattern 105 with which the first pad pattern 123 may directly contact. An area of an upper surface of the second pad pattern 125 may be greater than an area of an upper surface of the second end portion of the active pattern 105 with which the second pad pattern 125 may directly contact.

A plurality of first pad patterns 123 respectively disposed at the first end portions of the active patterns 105 of the active pattern row may define a first pad pattern row. In example embodiments, a plurality of first pad pattern rows may be spaced apart from each other in the first direction D1. A plurality of second pad patterns 125 respectively disposed at the second end portions of the active patterns 105 of the active pattern row may define a second pad pattern row.

In example embodiments, a plurality of second pad pattern rows may be spaced apart from each other in the first direction D1. The first pad pattern rows and the second pad pattern rows may be alternately and repeatedly arranged in the first direction D1.

In example embodiments, the upper surface of the first pad pattern 123 may be lower than the upper surface of the second pad pattern 125.

In example embodiments, each of the first and second pad patterns 123 and 125 may include silicon. Specifically, each of the first and second pad patterns 123 and 125 may include polysilicon or amorphous silicon.

The first fence pattern 127 may be formed between the first and second pad patterns 123 and 125 adjacent to each other in the first direction D1, and the first and second pad patterns 123 and 125 may be spaced apart from each other. Accordingly, a plurality of first fence patterns 127 may be spaced apart from each other in the first and second directions D1 and D2.

In example embodiments, some of the first fence patterns 127 may overlap the isolation pattern 110 that is between adjacent ones of the active pattern columns in the vertical direction, and others of the first fence patterns 127 may overlap the first insulation pattern 112 in the vertical direction.

In example embodiments, a lowermost surface of the first fence pattern 127 may be lower than a lowermost surface of each of the first and second pad patterns 123 and 125.

In example embodiments, the first fence pattern 127 may include, for example, a low dielectric material such as silicon oxide, silicon oxycarbide, etc.

The gate structure 170 may extend in the first direction D1 through the central portions of the active patterns 105 of the active pattern row and an upper portion of the isolation pattern 110, and a plurality of gate structures 170 may be spaced apart from each other in the second direction D2. The gate structure 170 may include a first conductive pattern 140, a second conductive pattern 150 and a gate mask 160 sequentially stacked in the vertical direction and may further include a gate insulation pattern 130 covering or overlapping sidewalls of the first conductive pattern 140, the second conductive pattern 150 and the gate mask 160 and a lower surface of the first conductive pattern 140.

The gate insulation pattern 130 may include, for example, an oxide such as silicon oxide, the first conductive pattern 140 may include, for example, a metal, a metal nitride, a metal silicide, the second conductive pattern 150 may include, for example, polysilicon doped with n-type impurities or p-type impurities, and the gate mask 160 may include, for example, an insulating nitride such as silicon nitride.

The first bit line structure may include a first bit line 290 and first spacers 240 at opposite sidewalls of the first bit line 290. The first bit line structure may extend in the second direction D2, and a plurality of first bit line structures may be spaced apart from each other in the first direction D1.

The first bit line 290 may be disposed on the upper surfaces of the first pad patterns 123 of the first pad pattern column to extend in the second direction D2, and a plurality of first bit lines 290 may be spaced apart from each other in the first direction D1. Accordingly, the first bit line 290 may overlap the first end portion of the active pattern 105 in the vertical direction, and the first pad pattern 123 may be formed between the first bit line 290 and the first end portion of the active pattern 105.

The first bit line 290 may include a first ohmic contact pattern 260, a third conductive pattern 270 and a first bit line mask 280 sequentially stacked in the vertical direction. In example embodiments, a plurality of first ohmic contact patterns 260 may be respectively disposed on the first pad patterns 123 to be spaced apart from each other in the second direction D2.

The first ohmic contact pattern 260 may include, for example, a metal silicide, and the third conductive pattern 270 may include, for example, a metal such as molybdenum, and the first bit line mask 280 may include, for example, silicon oxide, silicon oxycarbide, etc.

In example embodiments, the first bit line 290 may extend through or extend into an upper portion of the first pad pattern 123. Accordingly, a lower surface of the first bit line 290 may be lower than the upper surface of the second pad pattern 125 and higher than the upper surface of the second end portion of the active pattern 105.

In example embodiments, the first bit line 290 may also extend through or extend into an upper portion of the gate structure 170 adjacent to the first pad pattern 123 in the second direction D2 and an upper portion of the first fence pattern 127 adjacent to the first pad pattern 123 in the first direction D1.

The first spacer 240 is illustrated as a single layer, but the concept of the present invention is not limited thereto. That is, the first spacer 240 may include a plurality of layers each containing or including different materials.

In example embodiments, the first spacer 240 may include, for example, a low dielectric material such as silicon oxide, silicon oxycarbide, etc.

Hereinafter, the first bit line 290 and the first spacers 240 on opposite sidewalls in the first direction D1 of the first bit line 290 may be referred to as a first bit line structure.

The first contact plug 185 may be formed on the second pad pattern 125. Accordingly, the first contact plug 185 may at least partially overlap the second end portion of the active pattern 105 in the vertical direction, and the second pad pattern 125 may be formed between the first contact plug 185 and the second end portion of the active pattern 105.

The first contact plug 185 may contact the upper surface of the second pad pattern 125 on the second end portion of the active pattern 105. In example embodiments, a plurality of first contact plugs 185 may be spaced apart from each other in the second direction D2 between the first bit line structures, and the second fence pattern 195 may be formed between the first contact plugs 185 adjacent to each other in the second direction D2.

In example embodiments, the first contact plug 185 may include, for example, polysilicon doped with impurities, and the second fence pattern 195 may include, for example, insulating nitride such as silicon nitride.

The buffer layer structure may include first and second buffer layers 210 and 220 sequentially stacked in the vertical direction on the first contact plug 185 and the second fence pattern 195. The first buffer layer 210 may include, for example, a low dielectric material such as silicon oxide, silicon oxycarbide, etc., and the second buffer layer 220 may include, for example, a low dielectric material such as silicon nitride, silicon oxycarbonitride, etc.

In example embodiments, the buffer layer structure may extend in the second direction D2 on the first contact plugs 185 and the second fence patterns 195 alternately and repeatedly arranged in the second direction D2, and a plurality of buffer layer structures may be spaced apart from each other in the first direction D1.

The second mold layer 310 may be formed on the buffer layer structure and the first bit line structure. The second mold layer 310 may include, for example, a low dielectric material such as silicon oxide or silicon oxycarbide.

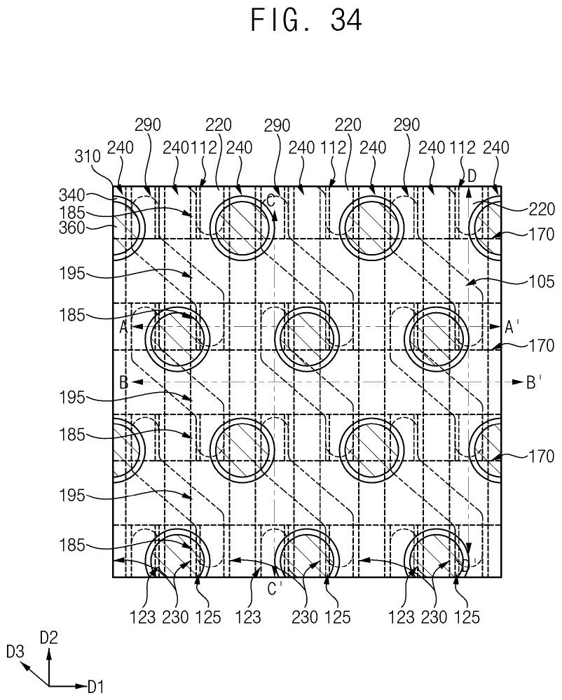

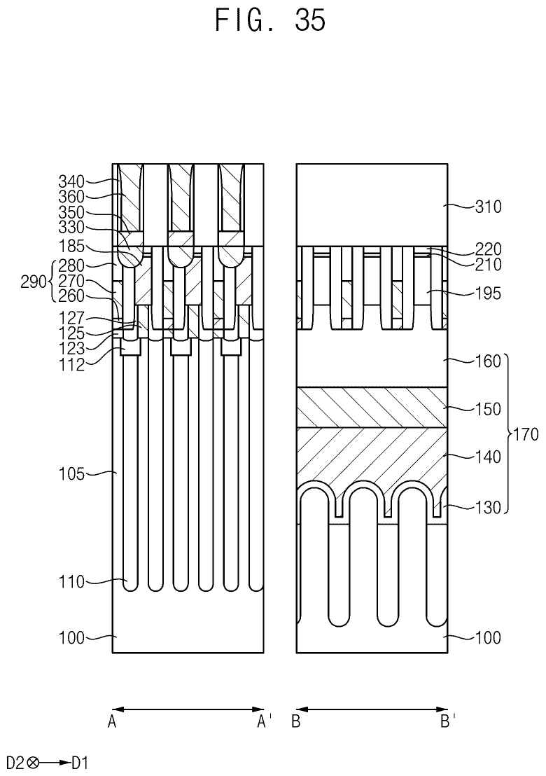

Referring to FIGS. 34 and 35 together with FIGS. 1 to 3, the contact plug structure may include a second contact plug 330, a second ohmic contact pattern 350 and a third contact plug 360 sequentially stacked in the vertical direction on a bottom of a third opening 320 extending through or extending into the second mold layer 310, the first bit line mask 280, the first spacer 240, the buffer layer structure and/or an upper portion of the first contact plug 185.

In example embodiments, a plurality of contact plug structures may be spaced apart from each other in each of the first and second directions D1 and D2, and may be arranged in a honeycomb pattern in a plan view. Each of the contact plug structures may have shape of, for example, a circle, an ellipse, a polygon, etc., in a plan view.

In example embodiments, the second contact plug 330 may include, for example, polysilicon doped with impurities, the second ohmic contact pattern 350 may include, for example, a metal silicide such as titanium silicide, cobalt silicide, nickel silicide, and the third contact plug 360 may include, for example, a metal such as tungsten.

The second spacer 340 may be formed between the second mold layer 310 and the third contact plug 360. The second spacer 340 may include, for example, a low dielectric material such as silicon nitride, silicon oxycarbonitride.

The capacitor 430 may include a lower electrode 400, a dielectric layer 410 and an upper electrode 420 sequentially stacked, and the lower electrode 400 may contact an upper surface of the third contact plug 360. Each of the lower and upper electrodes 400 and 420 may include, for example, a metal, a metal nitride, a metal silicide, silicon-germanium doped with impurities, etc., and the dielectric layer 410 may include, for example, a metal oxide with a high dielectric constant.

In a semiconductor device, the area the upper surface of the first end portion of the active pattern 105 may be reduced by the area of the upper surface of the first end of the active pattern 105 through which the first insulation pattern 112 may pass or extend into, and the area of the upper surface of the second end portion of the active pattern 105 may be reduced by the upper surface the second end of the active pattern 105 through which the first insulation pattern 112 may pass or extend into. Accordingly, a contact area of the first end portion of the active pattern 105 and the first bit line 290 and a contact area of the second end portion of the active pattern 105 and the first contact plug 185 may decrease. Accordingly, the electrical characteristics of the semiconductor device may deteriorate.

However, in the semiconductor device according to example embodiments, the first pad pattern 123 may be provided between the first end portion of the active pattern 105 and the first bit line 290, and the second pad pattern 125 may be provided between the second end portion of the active pattern 105 and the first contact plug 185. The area of the upper surface of the first pad pattern 123 may be greater than the area of the upper surface of the first end portion of the active pattern 105, and thus, the first bit line 290 and the first pad pattern 123 may have a relatively large contact area. Also, the area of the upper surface of the second pad pattern 125 may be greater than the area of the upper surface of the second end portion of the active pattern 105, and thus, the first contact plug 185 and the second pad pattern 125 may have a relatively large contact area. Accordingly, deterioration of the electrical characteristics of the semiconductor device may be reduced or prevented.

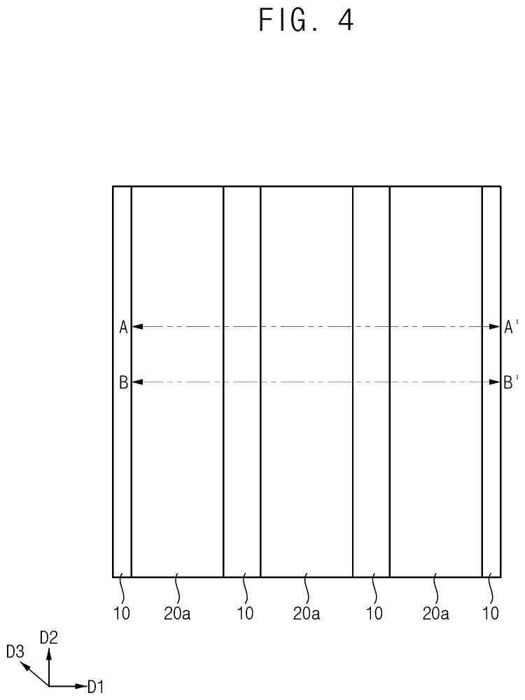

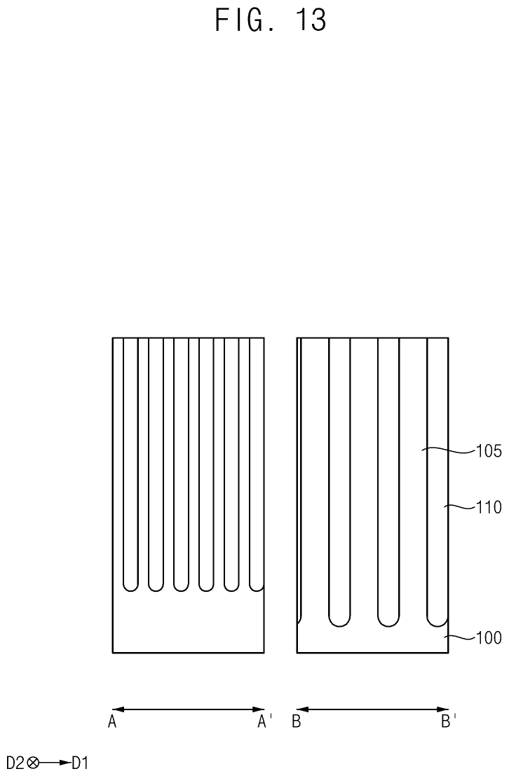

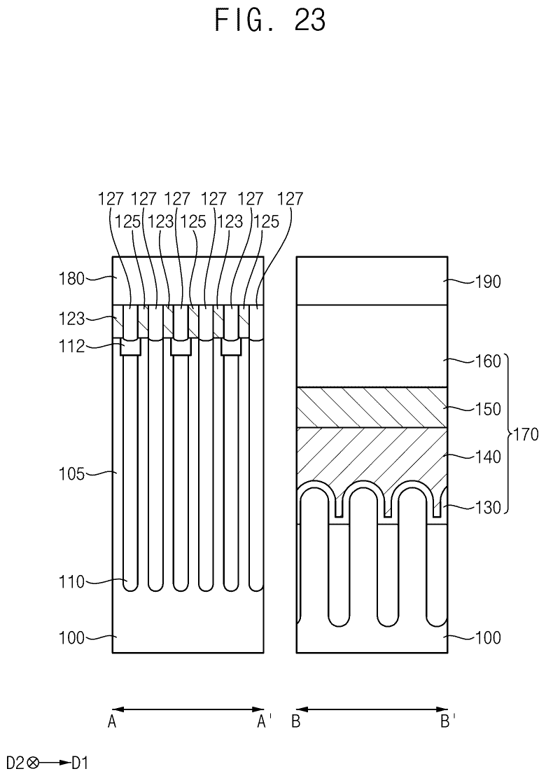

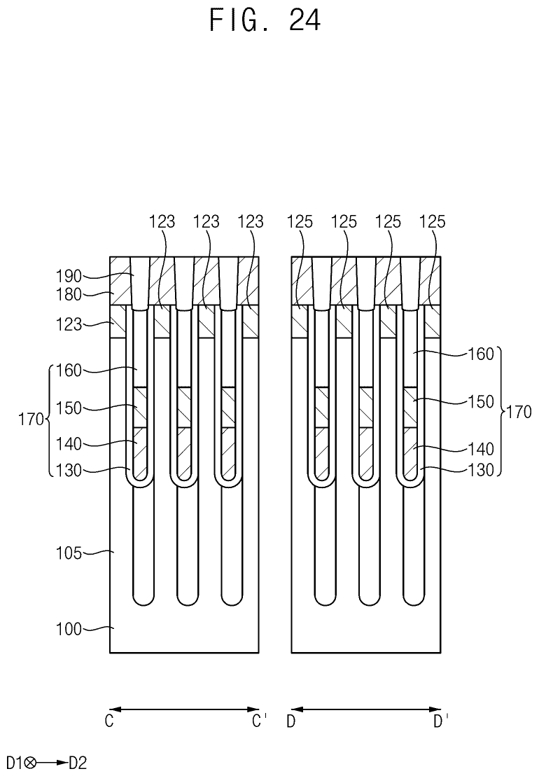

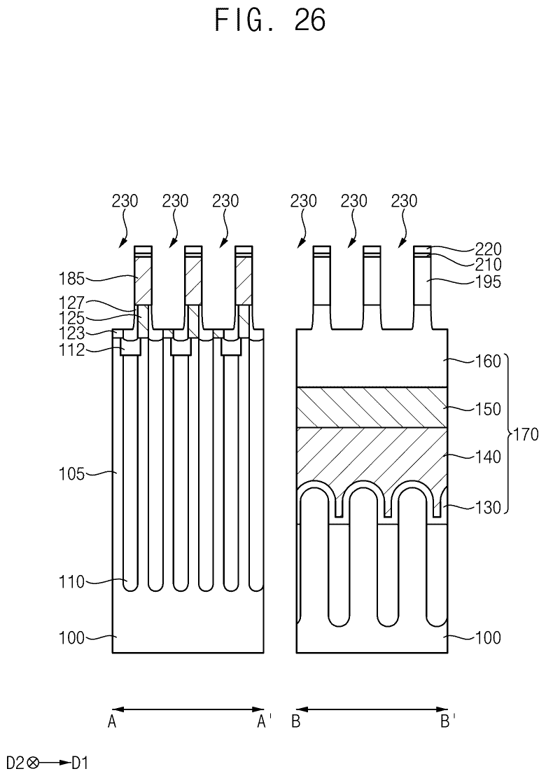

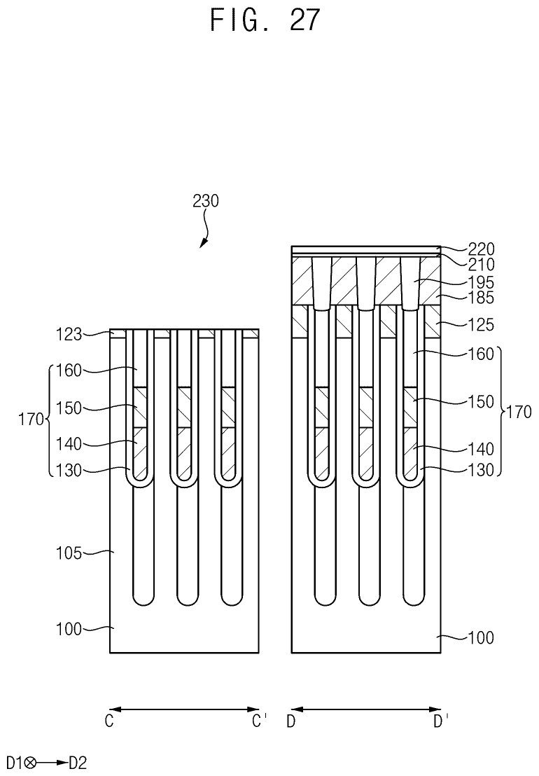

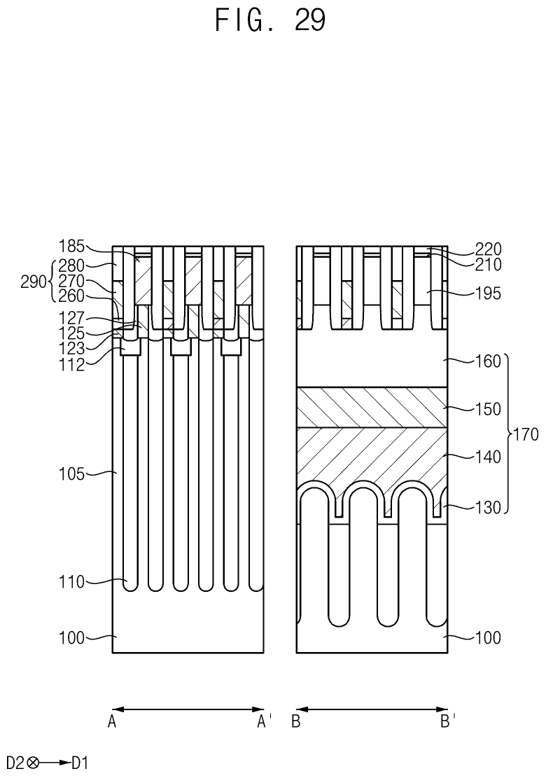

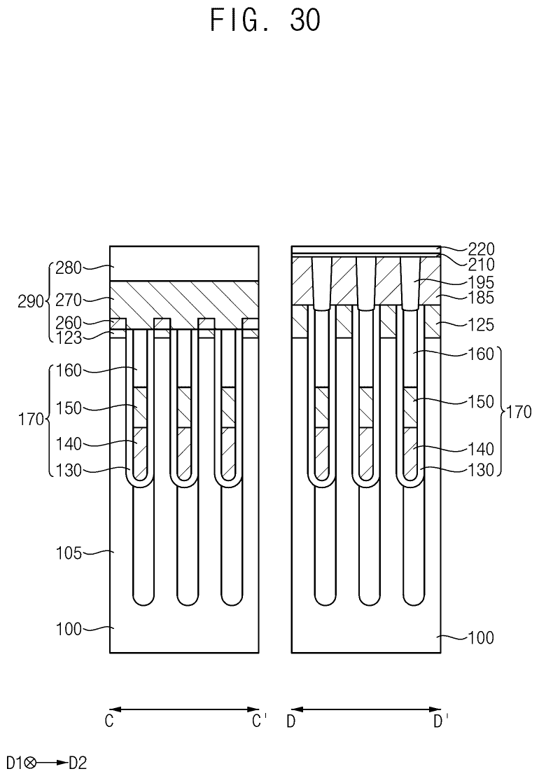

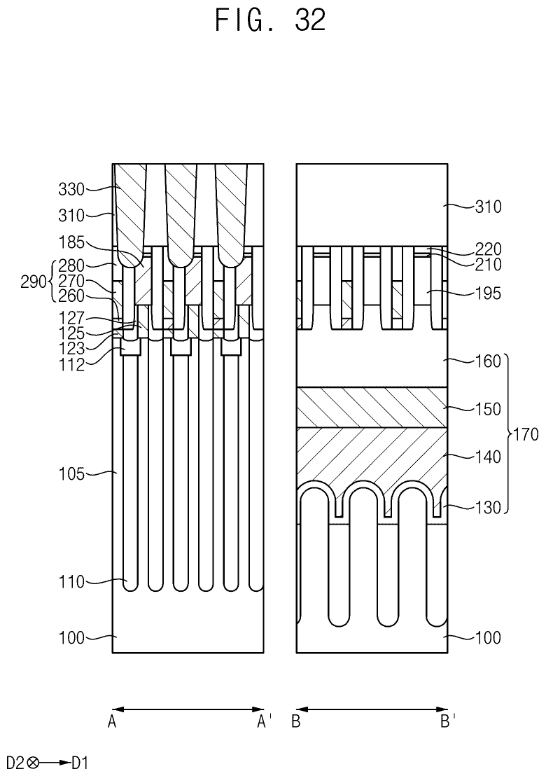

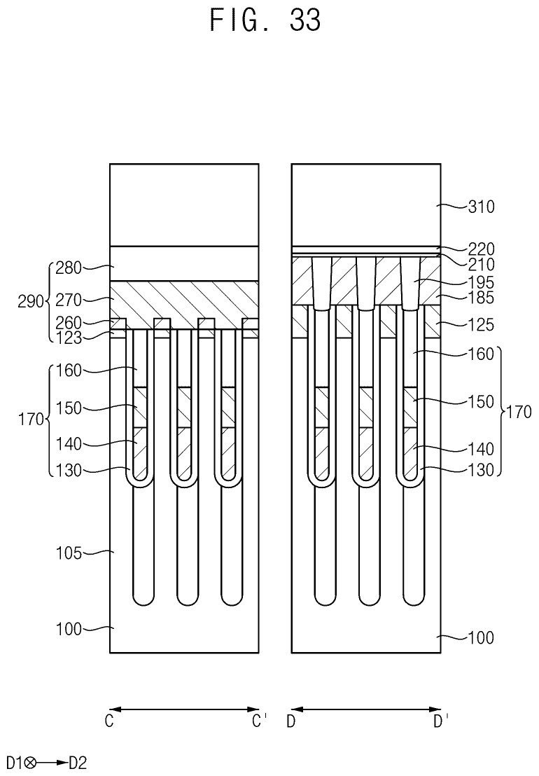

FIGS. 4 to 35 are plan views and cross-sectional views illustrating a method of manufacturing a semiconductor device according to example embodiments.

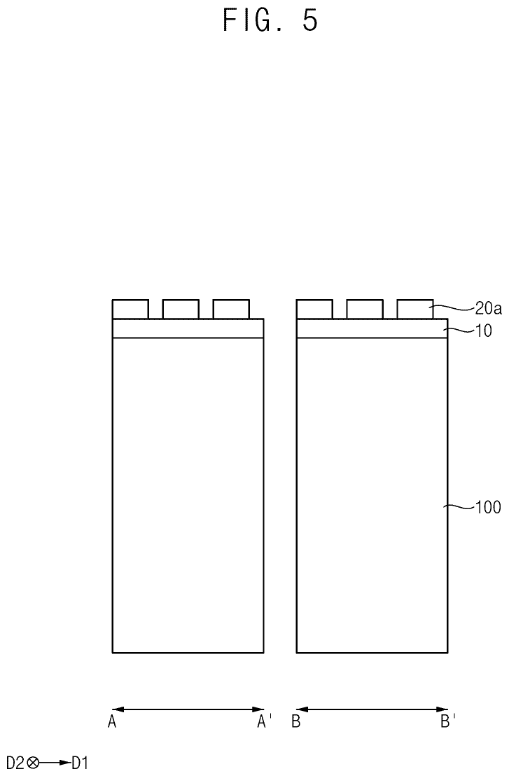

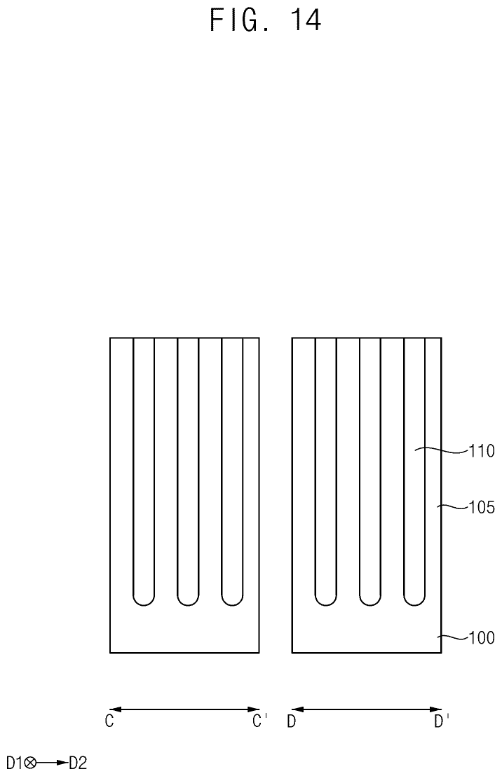

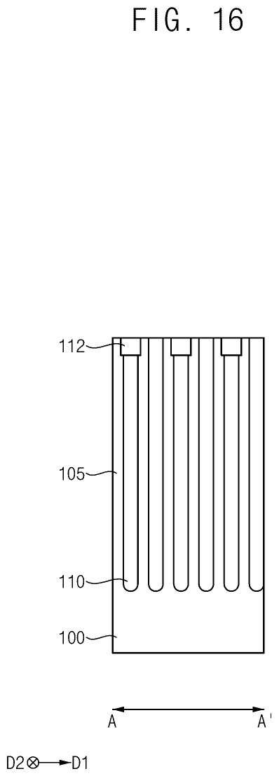

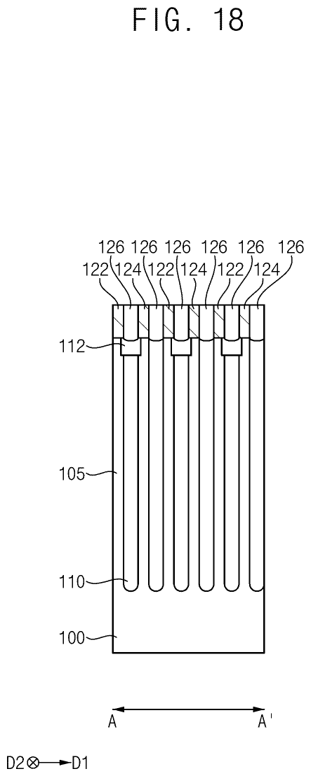

Specifically, FIGS. 4, 6, 8, 10, 12, 15, 17, 19, 22, 25, 28, 31 and 34 are the plan views, FIGS. 16 and 18 are cross-sectional views taken along lines A-A′ of corresponding plan views, FIGS. 5, 7, 9, 11, 13, 20, 23, 26, 29, 32 and 35 include cross-sectional views taken along lines A-A′ and B-B′ of corresponding plan views, and FIGS. 14, 21, 24, 27, 30 and 33 include cross-sectional views taken along lines C-C′ and D-D′ of corresponding plan views.

Referring to FIGS. 4 and 5, a hard mask layer 10 and a first mask layer may be sequentially formed on the substrate 100 in the vertical direction.

In example embodiments, the hard mask layer 10 may include a single layer or a plurality of layers each having different materials from each other. The hard mask layer 10 may include, for example, a metal oxide, silicon oxide, silicon oxynitride, silicon nitride, etc. The first mask layer may include a material having a high etch selectivity with respect to the hard mask layer 10, for example, silicon, but is not limited thereto.

A first patterning process may be performed on the first mask layer in a line shape extending in the second direction D2 to form a plurality of preliminary first mask 20a extending in the second direction D2. The preliminary first masks 20a may be spaced apart from each other in the first direction D1.

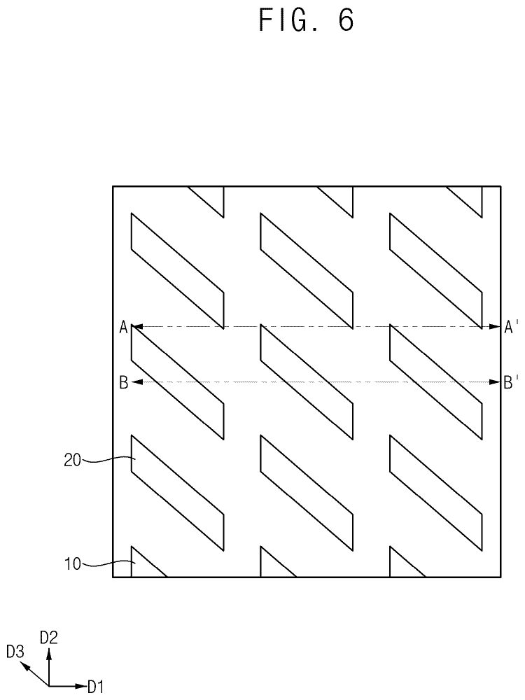

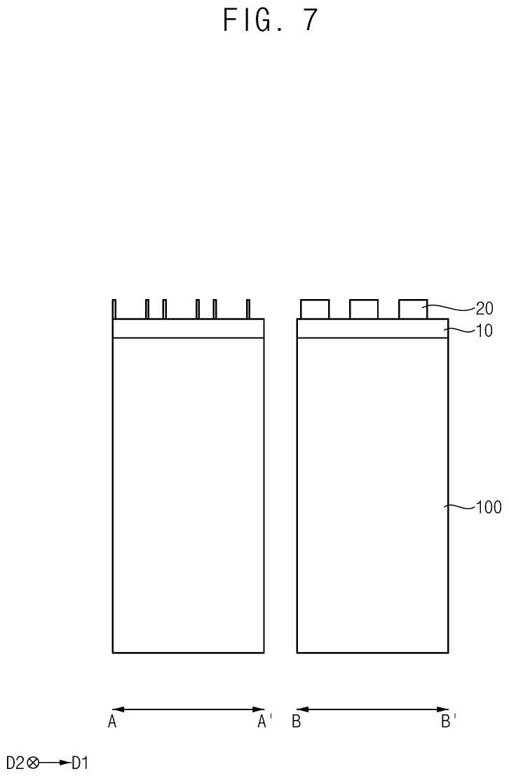

Referring to FIGS. 6 and 7, a second patterning process may be performed on the preliminary first mask 20a in a line shape extending in the third direction D3. Accordingly, the preliminary first mask 20a may be divided into a plurality of first masks 20 spaced apart from each other in the second direction D2.

In some embodiments, the second patterning process may be first performed first on the preliminary first mask 20a in a line shape extending in the third direction D3, and then the first patterning process may be performed on the first mask layer in a line shape extending in the second direction D2 so as to form the first masks 20.

The first mask 20 may correspond to a central portion of the active pattern 105 to be formed later.

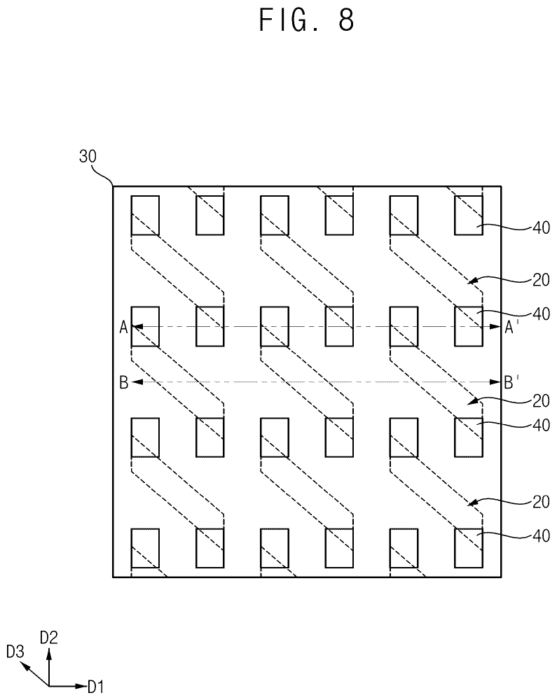

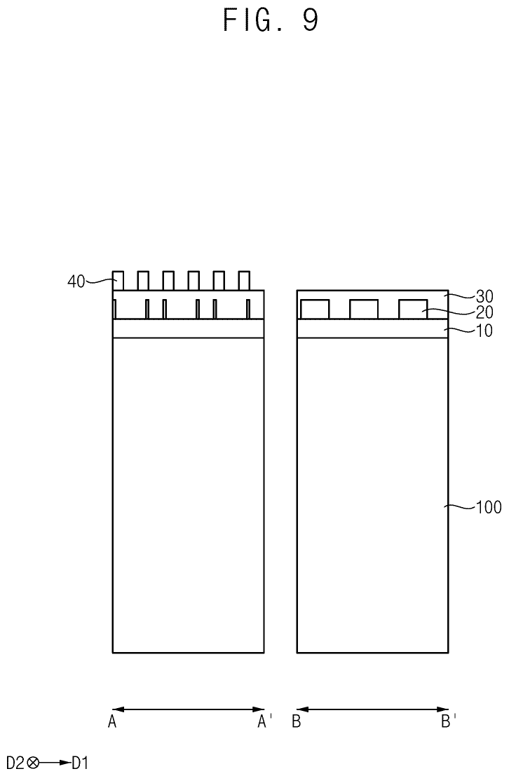

Referring to FIGS. 8 and 9, a first mold layer 30 and a second mask layer may be sequentially formed on the hard mask layer 10 and the first mask 20 in the vertical direction.

In example embodiments, the first mold layer 30 may include, for example, a carbon-containing layer such as Spin-On-Hardmask (SOH), silicon oxide, silicon oxynitride, silicon nitride, etc. The second mask layer may include a material having a high etch selectivity with respect to the first mold layer 30 and the hard mask layer 10, for example, silicon, but is not limited thereto.

A patterning process may be performed on the second mask layer to divide the second mask layer into a plurality of second masks 40. Each of the second masks 40 may be overlap an end portion in the third direction D3 of the first mask 20 in the vertical direction. Accordingly, the second masks may be spaced apart from each other in the first and second directions D1 and D2.

The second mask 40 may correspond to first or second end portions of the active pattern 105 to be formed later.

In example embodiments, the second mask 40 may be formed by a third patterning process performed in a line shape extending in the first direction D1 and a fourth patterning process performed in a line shape extending in the second direction D2. The order of the third and fourth patterning process is not limited.

The order of forming the first mask 20 and the second mask 40 is not limited. That is, the first mask 20 may be formed after forming the second mask 40.

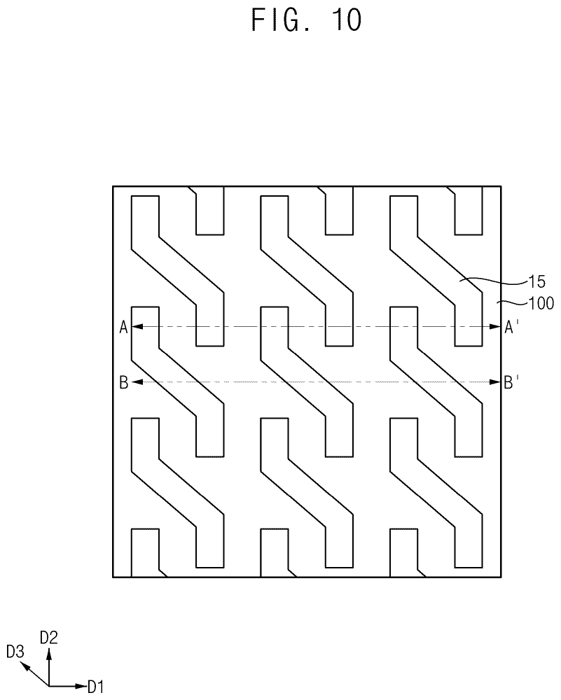

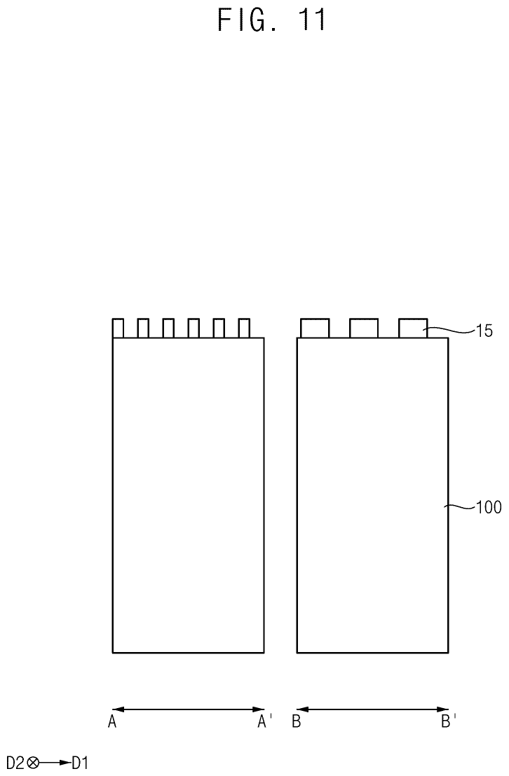

Referring to FIGS. 10 and 11, the hard mask layer 10 may be patterned by using the first and second masks 20 and 40 as etching masks. The hard mask layer 10 may be divided into a plurality of hard masks 15 by the etching process. The hard masks 15 may be spaced apart from each other in the first and second directions D1 and D2.

Each of the hard masks 15 may include a central portion corresponding to the first mask 20 and a first end portion and a second end portion each corresponding to the second mask 40. The central portion of the hard mask 15 may extend in the third direction D3 to a certain length. The first and second end portions of the hard mask 15 may be formed at opposite ends in the third direction D3 of the central portion, respectively. The first and second end portions of the hard mask 15 may extend in the second direction D2 away from the central portion to certain length, respectively.

The first and second masks 20 and 40 and the first mold layer 30 may be removed.

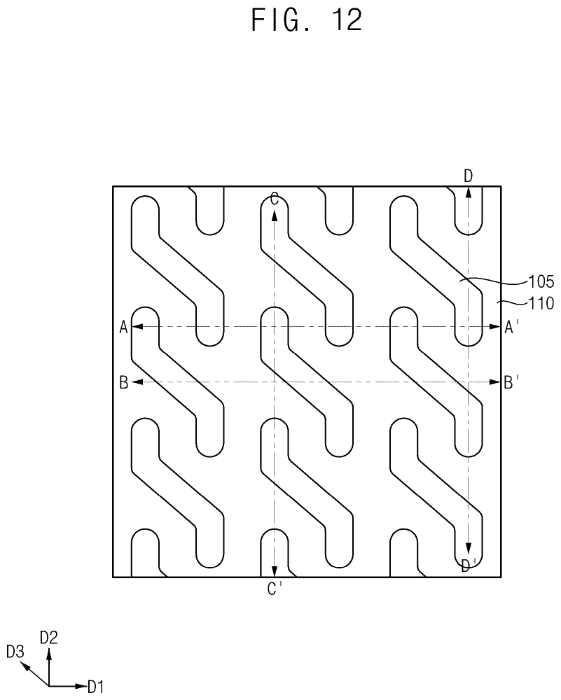

Referring to FIGS. 12 to 14, an etching process using the hard mask 15 as an etching mask may be performed on an upper portion of the substrate 100 to form a first recess. An active pattern 105 may be defined on the substrate 100 by the first recess. An isolation pattern 110 may be formed to fill the first recess.

The active pattern 105 may include a central portion, a first end portion and a second end portion corresponding to the central portion, the first end portion and the second end portion of the hard mask 15, respectively.

A plurality of active patterns 105 may be spaced apart from each other in the first and second directions D1 and D2, respectively, to define an active pattern array. A plurality of active patterns 105 of the active pattern array arranged along the first direction D1 may define an active pattern row. A plurality of active pattern rows may be spaced apart from each other in the second direction D2. A plurality of active patterns 105 of the active pattern array arranged along the second direction D2 may define an active pattern column. A plurality of active pattern columns may be spaced apart from each other in the first direction D1.

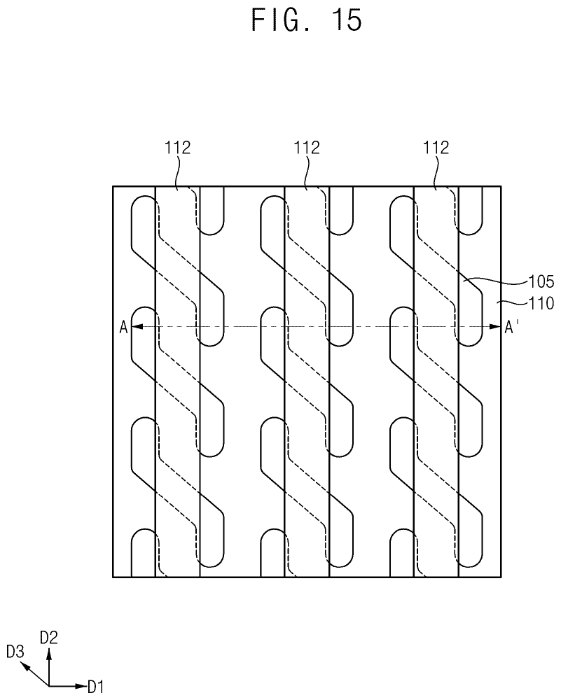

Referring to FIGS. 15 and 16, the central portion of the active patterns 105 of the active pattern row and the isolation pattern 110 adjacent thereto in the second direction D2 may be removed to form a second recess, and a first insulation pattern 112 may be formed within the second recess.

The second recess may be formed by partially removing the central portion of the active pattern 105 and upper portions of the first and second end portions of the active pattern 105 adjacent thereto. Accordingly, the first insulation pattern 112 may partially extend through or into not only the central portion of the active pattern 105 but also the first and second end portions of the active pattern 105 adjacent thereto. Accordingly, in a plan view, the first insulation pattern 112 may partially overlap the first and second end portions of the active pattern 105.

In example embodiments, the first insulation pattern 112 may extend in the second direction D2, and a plurality of first insulation patterns 112 may be spaced apart from each other in the first direction D1.

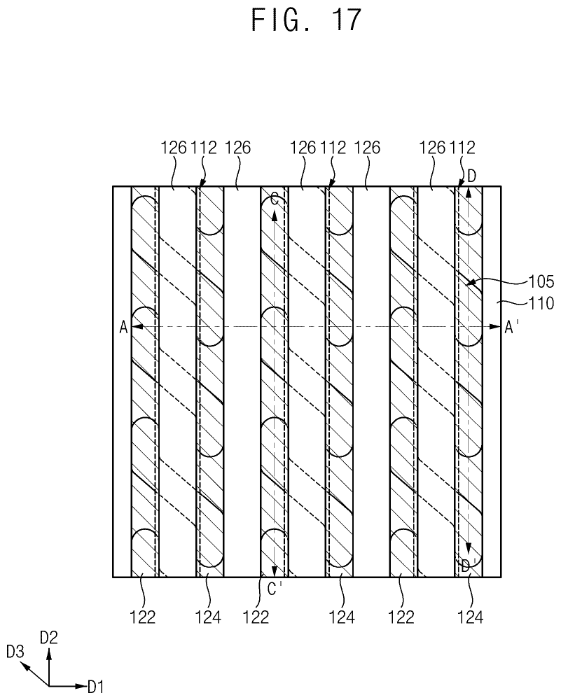

Referring to FIGS. 17 and 18, a pad layer may be formed on the active pattern 105, the first insulation pattern 112 and the isolation pattern 110. In example embodiments, the pad layer may be formed by a deposition process.

An etching process may be performed on the pad layer to divide the pad layer into a plurality of portions, each extending in the second direction D2 and spaced apart from each other in the first direction D1.

Hereinafter, a portion of the pad layer commonly overlapping the first end portions of the active patterns 105 of the active pattern column may be referred to as a first pad layer 122, and a portion of the pad layer commonly overlapping the second end portions of the active patterns 105 of the active pattern column may be referred to as the second pad layer 124. The first pad layers 122 and the second pad layers 124 may be alternately and repeatedly arranged in the first direction D1.

A first fence layer 126 may be formed to a sufficient height on the first and second pad layers 122 and 124, the active pattern 105 and the isolation pattern 110, and a planarization process may be performed until upper surfaces of the first and second pad layers 122 and 124 are exposed. Accordingly, a plurality of first fence layers 126 each extending in the second direction D2 may be spaced apart from each other in the first direction D1.

Referring to FIGS. 19 to 21, the first and second pad layers 122 and 124, the first fence layer 126, the first insulation pattern 112, an upper portion of the central portion of and the active pattern 105 and an upper portion of the isolation pattern 110 adjacent to the central portion of the active pattern 105 in the first direction D1 may be removed to form a third recess.

The first pad layer 122 may be divided into a plurality of first pad patterns 123 respectively disposed on the first end portions of the active patterns 105 of the active pattern column to be spaced apart from each other in the second direction D2, the second pad layer 124 may be divided into a plurality of second pad patterns 125 respectively disposed on the second end portions of the active patterns 105 of the active pattern column to be spaced apart from each other in the second direction D2, and the first fence layer 126 may be divided into a plurality of first fence patterns 127 spaced apart from each other in the second direction D2.

The third recess may completely penetrate the first insulation pattern 112 formed on the central portion of the active pattern 105 so that the first insulation pattern 112 is divided in the second direction D2. However, the concept of the present invention is not limited thereto. That is, depending on the depth of the first insulation pattern 112 and the depth of the gate structure 170, the first insulation pattern 112 may not be completely penetrated and may remain on the central portion of the active pattern 105. Accordingly, the first insulation pattern 112 may have a shape of a line extending in the second direction D2 in a plan view.

The first pad patterns 123 respectively disposed on the first end portions of the active patterns 105 of the active pattern column and arranged in the second direction D2 may define a first pad pattern column. A plurality of pad pattern columns may be spaced apart from each other in the first direction D1.

The second pad patterns 125 respectively disposed on the second end portions of the active patterns 105 of the active pattern column and arranged in the second direction D2 may define a second pad pattern column. A plurality of second pattern columns may be spaced apart from each other in the first direction D1.

A gate insulation layer may be formed on an inner sidewall of the third recess. A first conductive layer may be formed on the gate insulation layer, and an upper portion of the first conductive layer may be removed to form a first conductive pattern 140. A second conductive layer may be formed on the first conductive pattern 140 and the gate insulation layer, and an upper portion of the second conductive layer may be removed to form a second conductive pattern 150. A gate mask layer may be formed on the second conductive pattern 150 and the gate insulation layer, and a planarization process may be performed on the gate mask layer and the gate insulation layer until the upper surfaces of the first and second pad patterns 123 and 125 and an upper surface of the first fence pattern 127 are exposed to form a gate mask 160 and a gate insulation pattern 130, respectively.

The gate insulation pattern 130, the first and second conductive patterns 140 and 150 and the gate mask 160 within the third recess may together form the gate structure 170.

In example embodiments, the gate structure 170 may extend in the first direction D1 through the upper portions of the central portions of the active patterns 105 of the active pattern row, and a plurality of gate structures 170 may be spaced apart from each other in the second direction D2.

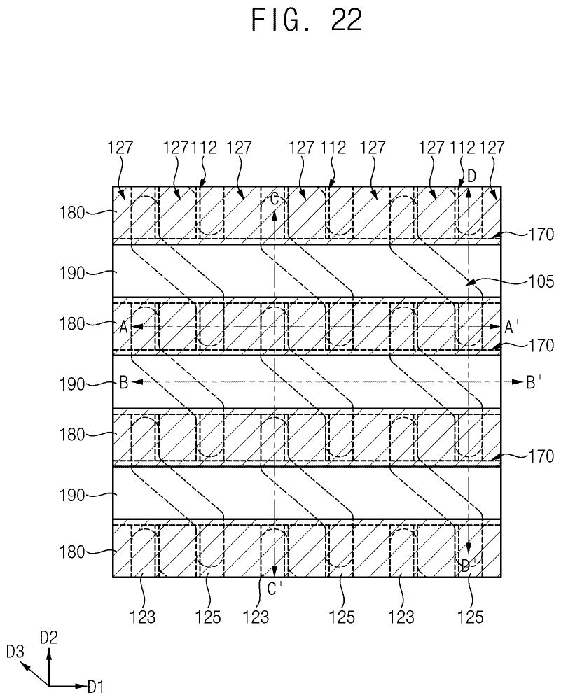

Referring to FIGS. 22 to 24, a first contact plug layer 180 may be formed on the first and second pad patterns 123 and 125, the first fence pattern 127 and the gate structure 170.

The first contact plug layer 180 may be etched to form a first opening exposing an upper surface of the gate structure 170. Accordingly, the first contact plug layer 180 may be divided into a plurality of parts extending in the first direction D1 and spaced apart from each other in the second direction D2.

A second fence layer 190 may be formed to a sufficient height within the first opening, and a planarizing process may be performed on an upper portion of the second fence layer 190 until an upper surface of the first contact plug layer 180 is exposed. Accordingly, the second fence layer 190 may be divided into a plurality of parts that each extend in the first direction D1 between the first contact plug layers 180 adjacent to each other in the second direction D2 on the gate structure 170, and spaced apart from each other in the second direction D2 by the first contact plug layers 180.

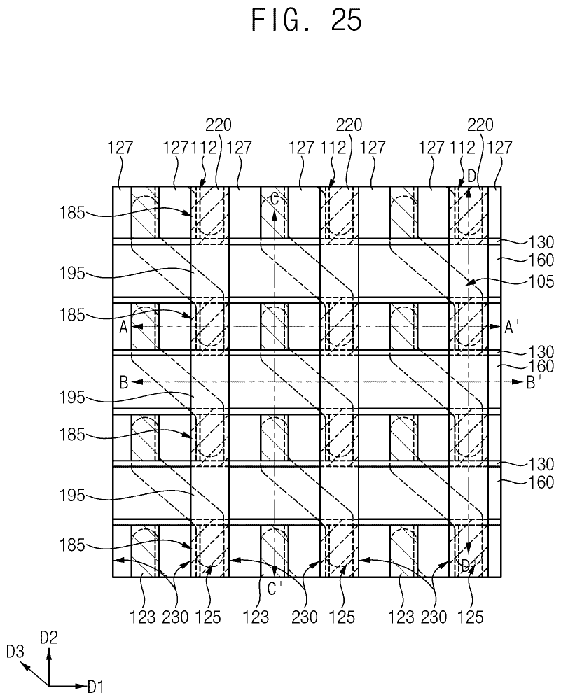

Referring to FIGS. 25 to 27, a first buffer layer 210 and a second buffer layer 220 may be sequentially formed on the first contact plug layer 180 and the second fence layer 190 in the vertical direction. The first and second buffer layers 210 and 220 may together form a buffer layer structure.

An etching process may be performed to form a second opening 230 extending through or extending into the buffer layer structure, the first contact plug layer 180, the second fence layer 190, an upper portion of the gate structure 170, an upper portion of the first pad pattern 123 and an upper portion of the first fence pattern 127. In example embodiments, the second opening 230 may extend in the second direction D2, and a plurality of second openings 230 may be spaced apart from each other in the first direction D1. Accordingly, upper surfaces of the first pad patterns 123 of the first pad pattern column and upper surfaces of the gate structures 170 adjacent thereto in the second direction D2 may be exposed by the second opening 230.

In example embodiments, the second opening 230 may also expose the upper surfaces of the first fence pattern 127 adjacent to the first pad pattern 123 in the first direction D1.

The first contact plug layer 180 may be divided into a plurality of first contact plugs 185 spaced apart from each other in the first direction D1, and the second fence layer 190 may be divided into a plurality of second fence patterns 195 spaced apart from each other in the first direction D1 by the etching process.

In example embodiments, the first contact plugs 185 may be respectively formed on the second pad patterns 125 and spaced apart from each other in the first and second directions D1 and D2. The second fence patterns 195 may be respectively formed between the second pad patterns 125 adjacent to each other in the second direction D2, and the second fence patterns 195 may be spaced apart from each other in the first and second directions D1 and D2.

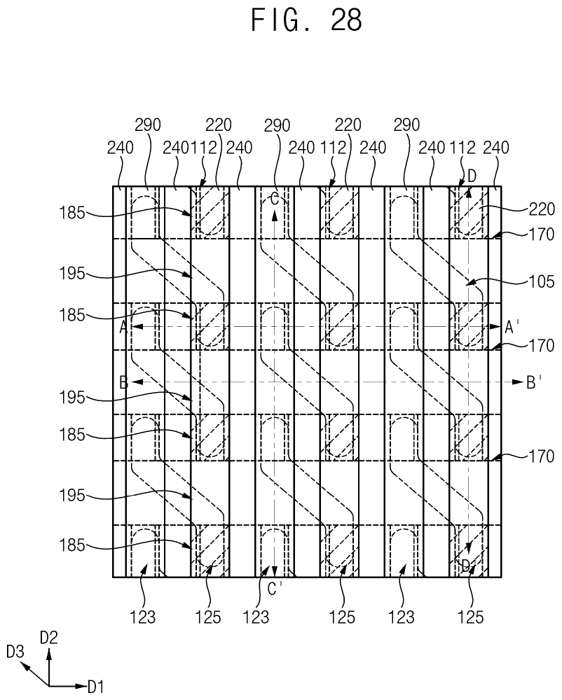

Referring to FIGS. 28 to 30, a first spacer layer may be formed, for example, conformally on a bottom and a sidewall of the second opening 230 and the second buffer layer 220, and a portion of the first spacer layer on the bottom of the second opening 230 may be removed by performing an anisotropic etching process on the first spacer layer. Accordingly, the upper surfaces of the first pad patterns 123 of the first pad pattern column and the upper surfaces of the gate structures 170 adjacent thereto in the second direction D2 may be exposed again. The first spacer layer may be transformed into a first spacer 240 on the sidewall of the second opening 230 by the etching process.

Meanwhile, referring to FIGS. 17 and 18 together with FIGS. 28 to 30, the first pad patterns 123 derived from the pad layer formed by the deposition process may be removed through the second opening 230. Accordingly, the upper surface of the first end portion of the active pattern 105 may be exposed, and an epitaxial growth process using the exposed upper surface of the first end portion of the active pattern 105 as a seed may be performed to form the first pad pattern 123 again.

A first metal layer may be formed on the upper surface of the first pad pattern 123 exposed by the second opening 230, an inner sidewall of the first spacer 240 and the upper surface of the second buffer layer 220, and a heat treatment process may be performed so that the first metal layer and the first pad pattern 123 may react with each other to form a first ohmic contact pattern 260. An unreacted portion of the first metal layer may be removed afterwards.

A third conductive layer may be formed on the first ohmic contact pattern 260 and the first spacer 240, and an upper portion of the third conductive layer may be removed to form a third conductive pattern 270. A first bit line mask layer may be formed on the third conductive pattern 270 and the first spacer 240, and the first bit line mask layer may be planarized until the upper surface of the second buffer layer 220 is exposed to form a first bit line mask 280.

The first ohmic contact pattern 260, the third conductive pattern 270 and the first bit line mask 280 may together form the first bit line 290.

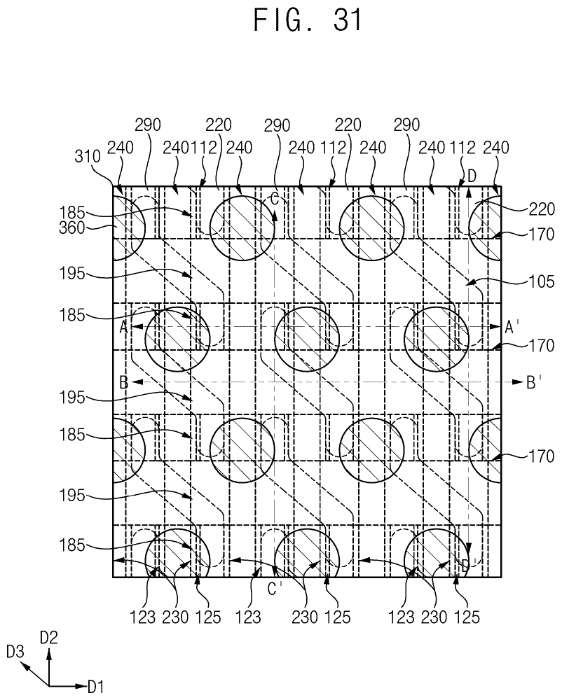

Referring to FIGS. 31 to 33, a second mold layer 310 may be formed on the second buffer layer 220 and the first bit line 290, and a third opening 320 extending through or extending into the second mold layer 310 may be formed to at least partially expose an upper surface of the first contact plug 185.

A second contact plug layer may be formed to a sufficient height to fill the third opening 320, and a planarization process may be performed on an upper portion of the second contact plug layer until an upper surface of the second mold layer 310 is exposed. Accordingly, the second contact plug layer may be divided into a plurality of second contact plugs 330.

Referring to FIGS. 34 and 35, an upper portion of the second contact plug 330 may be removed. Accordingly, an upper portion of the third opening 320 may be formed again. A second spacer layer may be formed on an upper surface of the second contact plug 330 exposed by the third opening 320 and an inner sidewall and the upper surface of the second mold layer 310, and an anisotropic etching process may be performed on the second spacer layer to form a second spacer 340. The upper surface of the second contact plug 330 may be exposed again.

A second ohmic contact pattern 350 may be formed on the exposed upper surface of the second contact plug 330. In example embodiments, the second ohmic contact pattern 350 may be formed by forming a second metal layer on the exposed upper surface of the second contact plug 330 and the second mold layer 310, performing a heat treatment thereon, and removing an unreacted portion of the second metal layer.

A third contact plug 360 may be formed on the second ohmic contact pattern 350 to fill the third opening 320. In example embodiments, the third contact plug 360 may be formed by forming a third contact plug layer to a sufficient height to fill the third opening 320 on the second ohmic contact pattern 350, and performing a planarization process on an upper portion of the third contact layer.

The second contact plug 330, the second ohmic contact pattern 350 and the third contact plug 360 may together form a contact plug structure.

In example embodiments, a plurality of contact plug structures may be spaced apart from each other in the first and second directions D1 and D2, and may be arranged in a honeycomb pattern in a plan view. Each of the contact plug structures may have shape of, for example, a circle, an ellipse, a polygon, etc., in a plan view.

Referring to FIGS. 1 to 3 again, a third mold layer may be formed on the second mold layer 310 and the third contact plug 360.

An etching process may be performed on the third mold layer to form a fourth opening exposing an upper surface of the third contact plug 360.

As the contact plug structures are arranged in a honeycomb pattern in a plan view, a plurality of fourth openings exposing the upper surfaces of the contact plug structures may also be arranged in a honeycomb pattern in a plan view.

A lower electrode 400 having a shape of a pillar may be formed in the fourth opening, the third mold layer may be removed, a dielectric layer 410 and an upper electrode 420 may be sequentially formed on the lower electrode 400 and the second mold layer 310. The lower electrode 400, the dielectric layer 410 and upper electrode 420 sequentially stacked may together form a capacitor 430.

In some embodiments, the lower electrode 400 may be formed to have a shape of a cylinder within the fourth opening.

Thereafter, manufacturing of the semiconductor device may be completed by additionally forming upper wirings on the capacitor 430.

As described above, the first and second pad patterns 123 and 125 may be additionally formed on the first and second end portions of the active pattern 105, so that the electrical connection between the first end portion and the first bit line 290 and the electrical connection between the second end portion of the active pattern 105 and the first contact plug 185 may be improved.

In addition, the first and second pad layers 122 and 124 may be divided in the second direction D2 to form the first and second pad patterns 123 and 125 by the process of forming the gate structure 170 that extends in the first direction D1. Accordingly, electrical properties of the semiconductor may be improved without adding excessive processes.

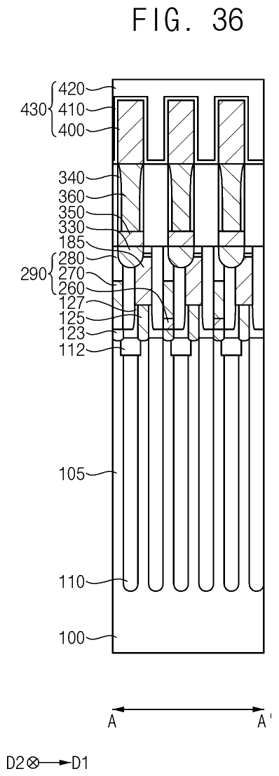

FIG. 36 is a cross-sectional view illustrating a semiconductor device in accordance with example embodiments. The semiconductor device may be substantially the same as or similar that of FIGS. 1 to 3, except for shapes of the first and second pad patterns 123 and 125 and the first fence pattern 127, and thus, repeated explanations are omitted herein.

Referring to FIG. 36, unlike the semiconductor device illustrated with reference to FIGS. 1 to 3, the lowermost surface of each of the first and second pad patterns 123 and 125 may be lower than the lowermost surface of the first fence pattern 127.

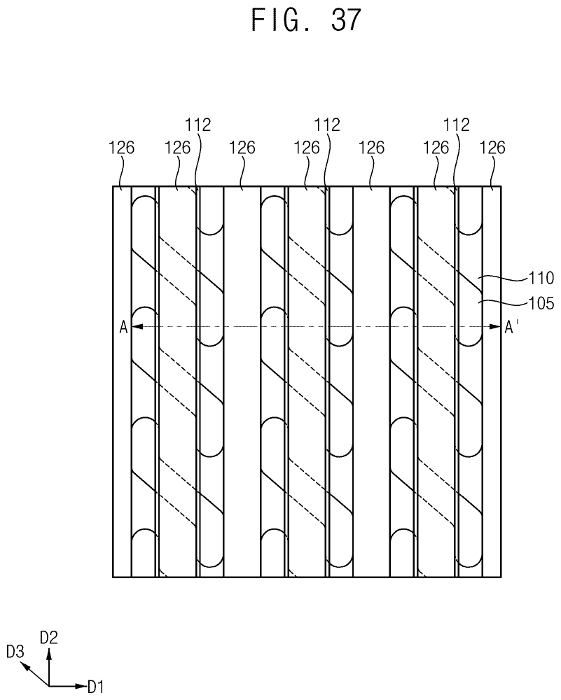

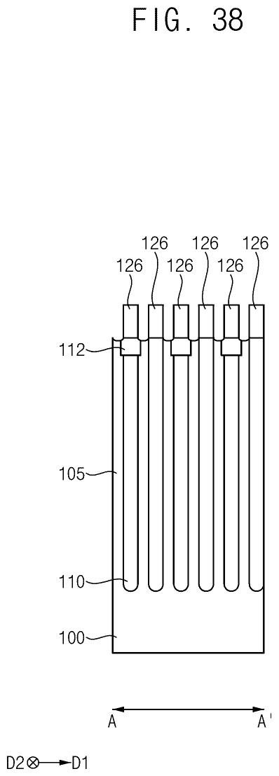

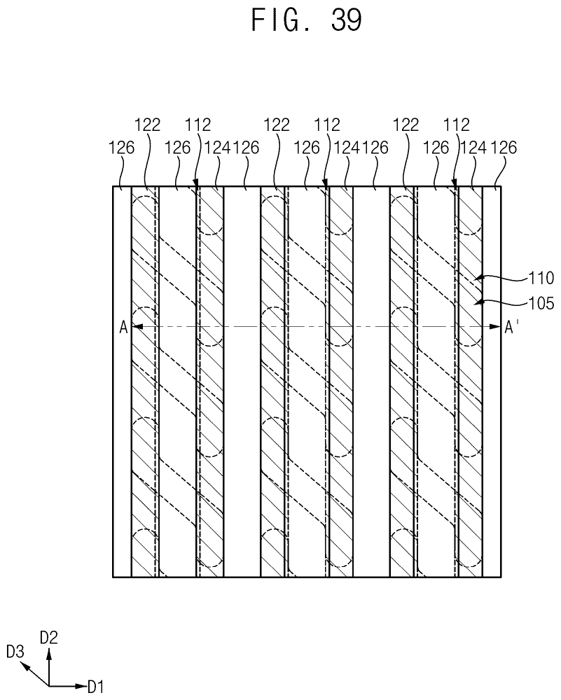

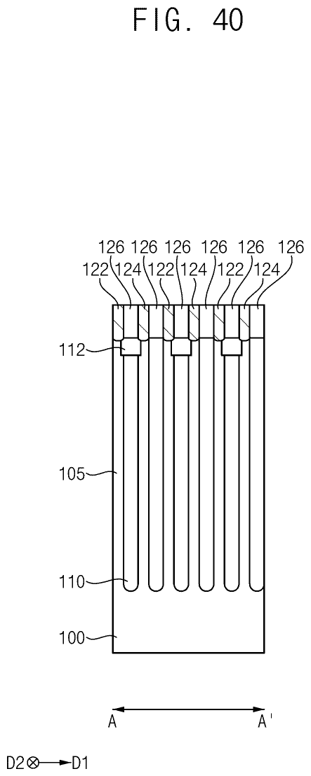

FIGS. 37 to 40 are plan views and cross-sectional views illustrating a method of forming the semiconductor device illustrated with reference to FIG. 36. Specifically, FIGS. 37 and 39 are the plan view, and FIGS. 38 and 40 are cross-sectional views taken along lines A-A′ of corresponding plan views. This method may include processes substantially the same as or similar to those illustrated with reference to FIGS. 1 to 35, and thus repeated explanations thereof are omitted herein.

Referring to FIGS. 37 and 38, processes substantially the same as or similar to those illustrated with reference to FIGS. 4 to 16 may be performed. Thereafter, unlike the processes illustrated with reference to FIGS. 17 and 18, the first fence layer 126 may be formed on the active pattern 105 and the isolation pattern 110.

An etching process may be performed on the first fence layer 126 to form a fifth opening exposing the upper surfaces of the first end portions of the active patterns 105 of the active pattern column and the upper surface of the isolation pattern 110 adjacent thereto in the second direction D2, and a sixth opening exposing the upper surfaces of the second end portions of the active patterns 105 of the active pattern column and the upper surface of the isolation pattern 110 adjacent thereto in the second direction D2.

During the etching process, the fifth and sixth openings may partially extend through the upper portions of the first and second end portions of the active pattern 105, respectively.

In example embodiments, the fifth opening may expose a portion of the upper surface of the first insulation pattern 112 adjacent to the first end portion of the active pattern 105 in the first direction D1 and the sixth opening may expose a portion of the upper surface of the first insulation pattern 112 adjacent to the second end portion of the active pattern 105 in the first direction D1.

In example embodiments, the fifth opening may extend in the second direction D2 and a plurality of fifth openings may be spaced apart from each other in the first direction D1. The sixth opening may extend in the second direction D2, and a plurality of sixth openings may be spaced apart from each other in the first direction D1. The fifth openings and the sixth openings may be alternately and repeatedly formed along the first direction D1.

The first fence layer 126 may be divided into a plurality of parts each extending in the second direction D2 and spaced apart from each other in the first direction D1.

Referring to FIGS. 39 and 40, for example, a deposition process may be performed to form the pad layer to a sufficient height to fill the fifth and sixth openings, and a planarization process may be performed on an upper portion of the pad layer until an upper surface of the first fence layer 126 is exposed. Accordingly, the first pad layer 122 may be formed in the fifth opening, and the second pad layer 124 may be formed in the sixth opening.

The first pad layer 122 may extend in the second direction D2 to contact the upper surfaces of the first end portions of the active patterns 105 of the active pattern column, and the second pad layer 124 may extend in the second direction D2 to contact the upper surfaces of the second end portions of the active patterns 105 of the active pattern column.

The first pad layers 122 and the second pad layers 124 may also be arranged alternately and repeatedly in the direction D1 corresponding to the fifth and sixth openings.

In some embodiments, an epitaxial growth process using the upper surfaces of the first and second end portions of the active pattern 105 exposed by the fifth and sixth openings as seeds may be performed to form the first and second pad layers 122 and 124. Accordingly, a plurality of first pad layers 122 may be respectively formed on the first end portions of the active patterns 105 exposed by the fifth opening so that the first pad layers 122 may be spaced apart from each other in the second direction D2, and a plurality of second pad layers 124 may be respectively formed on the second end portions of the active patterns 105 exposed by the sixth opening so that the second pad layers 124 may be spaced apart from each other in the second direction D2.

Thereafter, manufacturing of the semiconductor device may be completed by performing processes substantially the same as or similar to the processes illustrated with reference to FIGS. 19 to 35 and FIGS. 1 to 3.

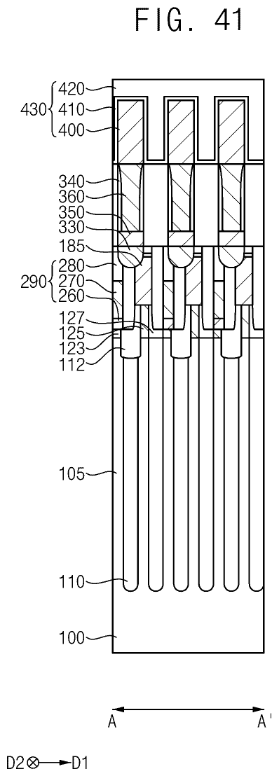

FIG. 41 is a cross-sectional view illustrating a semiconductor device in accordance with example embodiments. The semiconductor device may be substantially the same as or similar that of FIGS. 1 to 3, except for shapes and arrangement of the first insulation pattern 112, the first and second pad patterns 123 and 125 and the first fence pattern 127, and thus, repeated explanations are omitted herein.

Referring to FIG. 41, an uppermost surface of the first insulation pattern 112 may be substantially coplanar with the upper surface of the second pad pattern 125 and the upper surface of the first fence pattern 127.

The first and second pad patterns 123 and 125 facing each other in the first direction D1 and a portion of the first insulation pattern 112 therebetween may be defined as a first repeating unit. A plurality of first repeating units may be spaced apart from each other in the first and second directions D1 and D2. The first fence pattern 127 may be formed between the first repeating units adjacent to each other in the first direction D1.

In example embodiments, the first fence pattern 127 may overlap in the vertical direction a portion of the isolation pattern 110 between the active pattern columns adjacent to each other in the first direction D1.

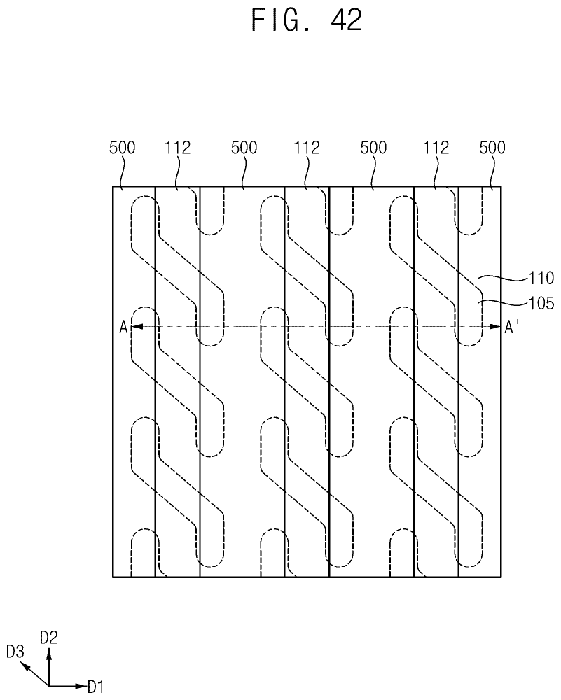

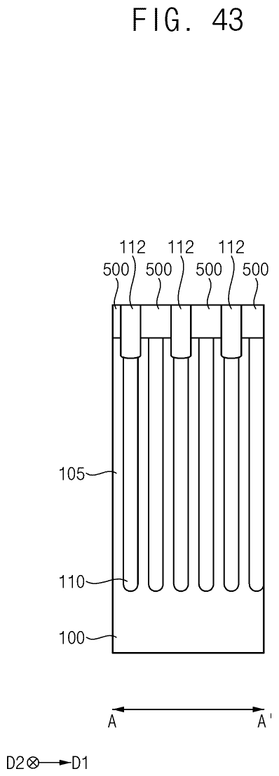

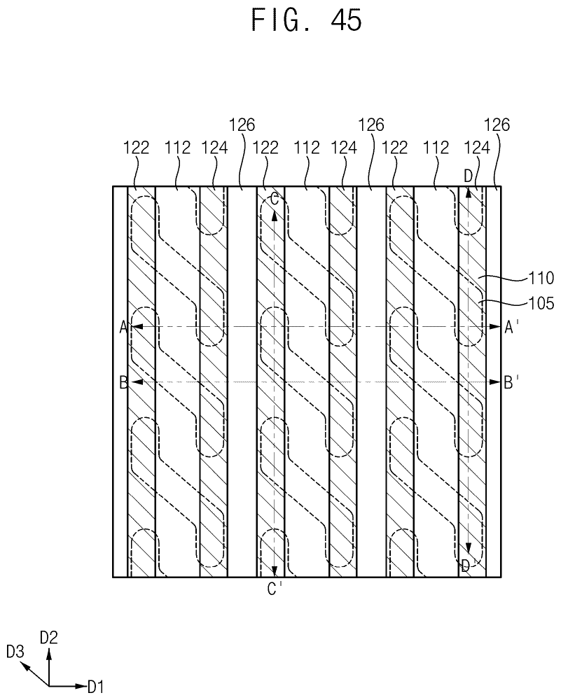

FIGS. 42 to 46 are plan views and cross-sectional views illustrating a method of forming a semiconductor device in accordance with example embodiments. Specifically, FIGS. 42 and 45 are the plan view, and FIGS. 43, 44, and 46 are cross-sectional views taken along lines A-A′ of corresponding plan views. This method may include processes substantially the same as or similar to those illustrated with reference to FIGS. 1 to 35, and thus repeated explanations thereof are omitted herein.

Referring to FIGS. 42 and 43, processes substantially the same as or similar to those illustrated with reference to FIGS. 4 to 16 may be performed. Thereafter, unlike the processes illustrated with reference to FIGS. 17 and 18, the fourth mold layer 500 may be formed on the active pattern 105 and the isolation pattern 110.

Thereafter, an etching process may be performed on the fourth mold layer 500 to form a seventh opening extending through or extending into the central portion of the active pattern 105 and an upper portion of the isolation pattern 110 adjacent thereto in the second direction D2.

The fourth mold layer 500 may be divided into a plurality of parts each extending in the second direction D2 and spaced apart from each other in the first direction D1 by the etching process.

The first insulation pattern 112 may be formed in the seventh opening. The first insulation pattern 112 may be formed by forming a first insulating layer to a sufficient height within the seventh opening, and performing a planarization process on an upper portion of the first insulating layer until an upper surface of the fourth mold layer 500 is exposed.

In example embodiments, the first insulation pattern 112 may extend in the second direction D2 through the central portions of the active patterns 105 of the active pattern column and the upper portion of the isolation pattern 110 adjacent thereto in the second direction D2, and the plurality of the first insulation patterns 112 may be spaced apart from each other in the first direction D1. The first insulation pattern 112 may also extend through portions of the first and second end portions of the active pattern 105 adjacent to the central portion of the active pattern 105.

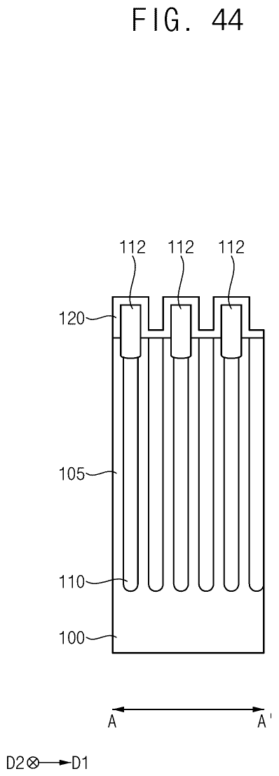

Referring to FIG. 44, the fourth mold layer 500 may be removed. Accordingly, the upper surfaces of the first and second end portions of the active pattern 105 and the upper surface of the isolation pattern 110 adjacent thereto in the second direction D2 may be exposed.

The pad layer may be formed, for example, conformally on the upper surface and opposite sidewalls of the first insulation pattern 112, the upper surfaces of the first and second end portions of the active pattern 105 and the upper surface of the isolation pattern 110.

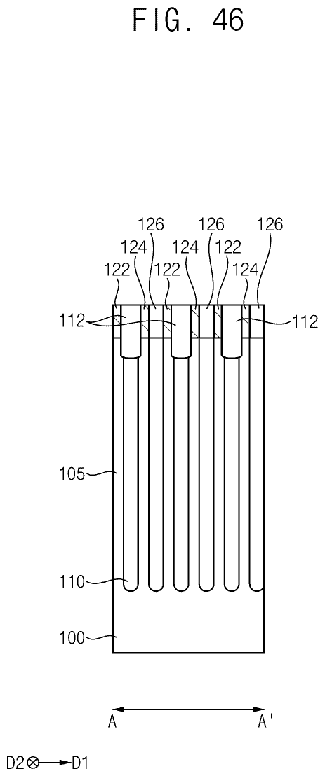

Referring to FIGS. 45 and 46, an anisotropic etching process may be performed on the pad layer. Accordingly, the first pad layer 122 and the second pad layer 124 may be formed on the opposite sidewalls of the first insulation pattern 112, respectively.

The first pad layer 122 may extend in a second direction D2 along the upper surfaces of the first end portions of the active patterns 105 of the active pattern column, and the second pad layer 124 may extend in the second direction D2 along the upper surfaces of the second end portions of the active patterns 105 of the active pattern column.

Hereinafter, the first insulation pattern 112 and the first and second pad layers 122 and 124 respectively on the opposite sidewalls thereof may be referred to as an extension structure. In example embodiments, the extension structure may extend in the second direction D2 and a plurality of extension structures may be spaced apart from each other in the first direction D1.

The first fence layer 126 may be formed in the seventh opening. The first fence layer 126 may be formed by, for example, forming the first fence layer 126 to a sufficient height to fill the seventh opening, and performing a planarization process on an upper portion of the first fence layer 126 until an upper surface of the extension structure is exposed.

In example embodiments, the first fence layer 126 may extend in the second direction D2 between the extension structures adjacent to each other in the second direction D2, and accordingly, a plurality of first fence layers 126 may be spaced apart from each other in the first direction D1.

Thereafter, manufacturing of the semiconductor device may be completed by performing processes substantially the same as or similar to the processes illustrated with reference to FIGS. 19 to 35 and FIGS. 1 to 3.

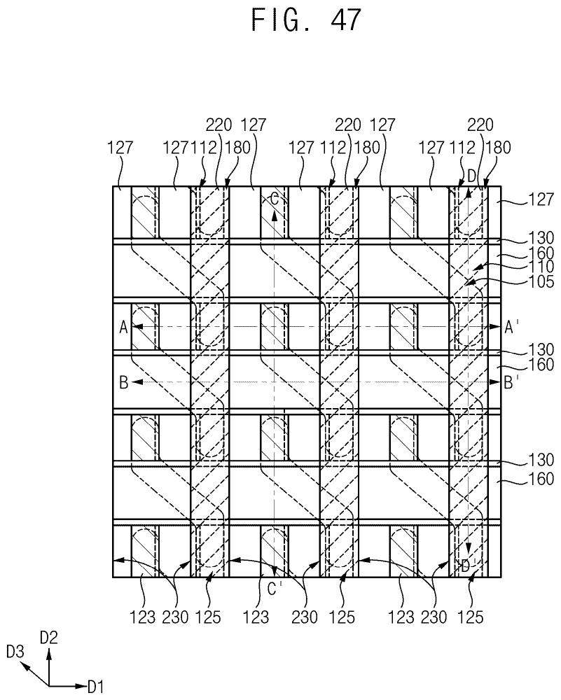

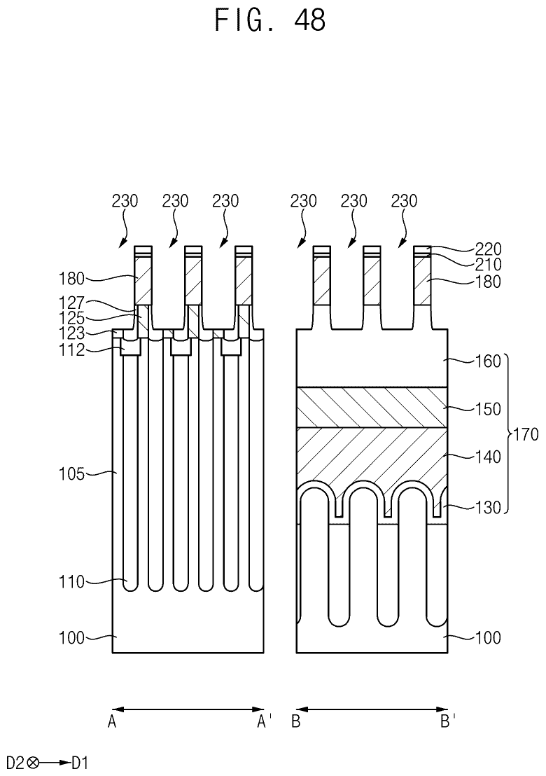

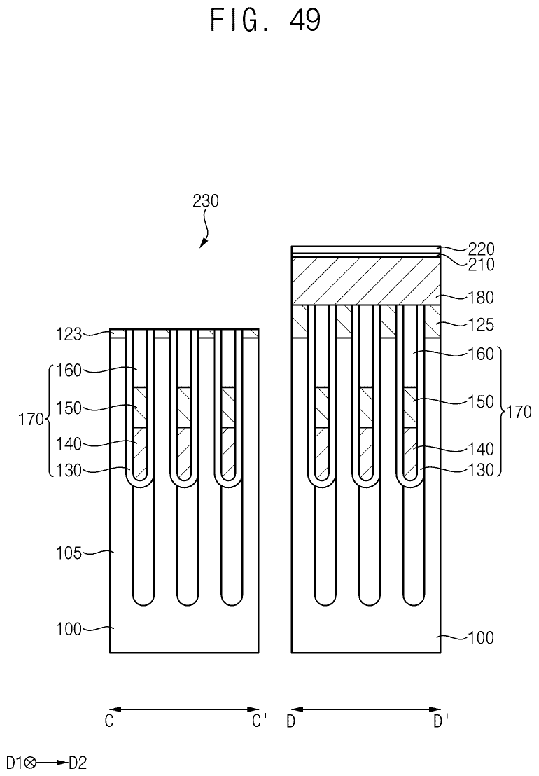

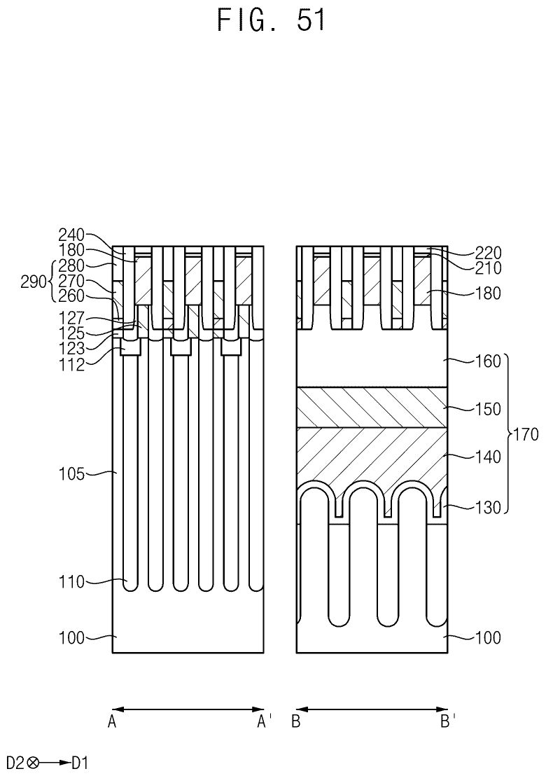

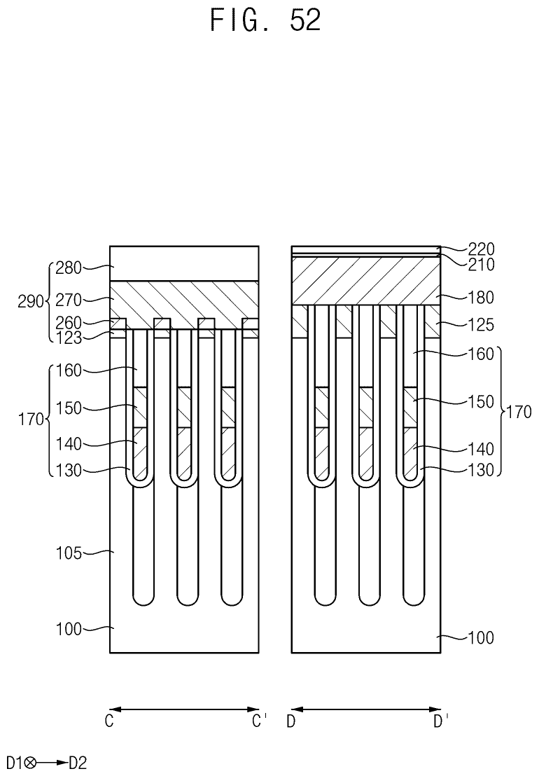

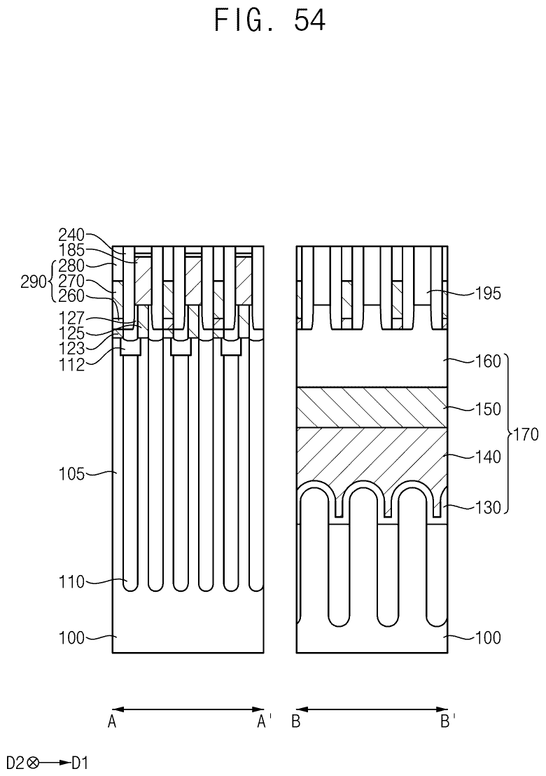

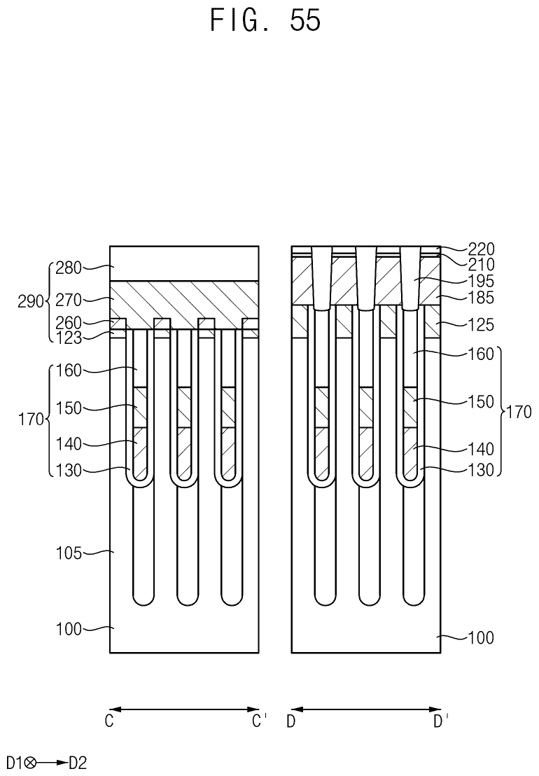

FIGS. 47 to 55 are plan views and cross-sectional views illustrating a method of forming a semiconductor device in accordance with example embodiments. Specifically, FIGS. 47, 50 and 53 are the plan view, FIGS. 48, 51 and 54 include cross-sectional views taken along lines A-A′ and B-B′ of corresponding plan views, and FIGS. 49, 52 and 55 include cross-sectional views taken along lines C-C′ and D-D′ of corresponding plan views.

This method may include processes substantially the same as or similar to those illustrated with reference to FIGS. 1 to 35, except for processes of forming of the first contact plug 185, the second fence pattern 195 and the first bit line 290 illustrated with reference to FIGS. 22 to 30, and thus repeated explanations thereof are omitted herein.

Referring to FIGS. 47 to 49, after performing processes substantially the same as or similar to those illustrated with reference to FIGS. 4 to 21, the first contact plug layer 180 and the buffer layer structure may be sequentially formed on the first and second pad patterns 123 and 125 and the first fence pattern 127 in the vertical direction. The buffer layer structure may include the first buffer layer 210 and the second buffer layer 220 sequentially stacked in the vertical direction.

An etching process may be performed on the buffer layer structure and the first contact plug layer 180 to form the second opening 230 exposing the upper surfaces of the first end portions of the active patterns 105 of the active pattern column.

The first contact plug layer 180 may be divided into a plurality of parts each extending in the second direction D2 and spaced apart from each other in the first direction D1 by the etching process.

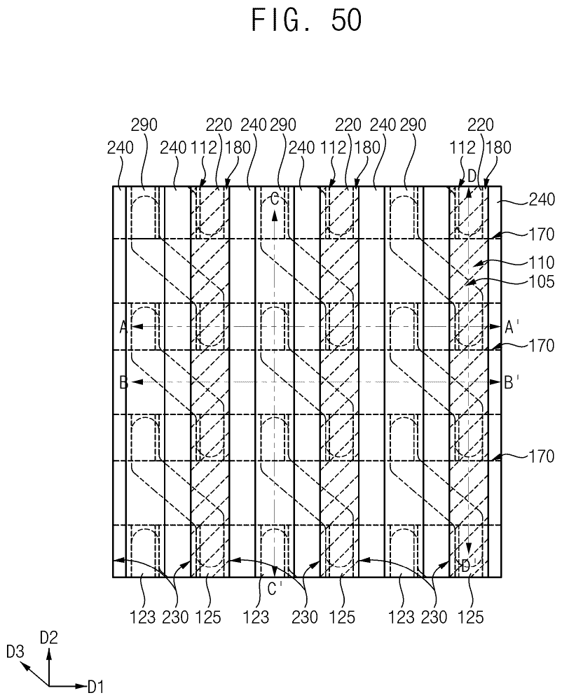

Referring to FIGS. 50 to 52, the first spacer 240 may be formed on the sidewall of the second opening 230. Thereafter, the first bit line 290 including the first ohmic contact pattern 260, the third conductive pattern 270 and the first bit line mask 280 sequentially stacked on the bottom of the second opening 230 may be formed.

Hereinafter, the first bit line 290 and the first spacers 240 formed on the opposite sidewalls of the first bit line 290 may be referred to as the first bit line structure together.

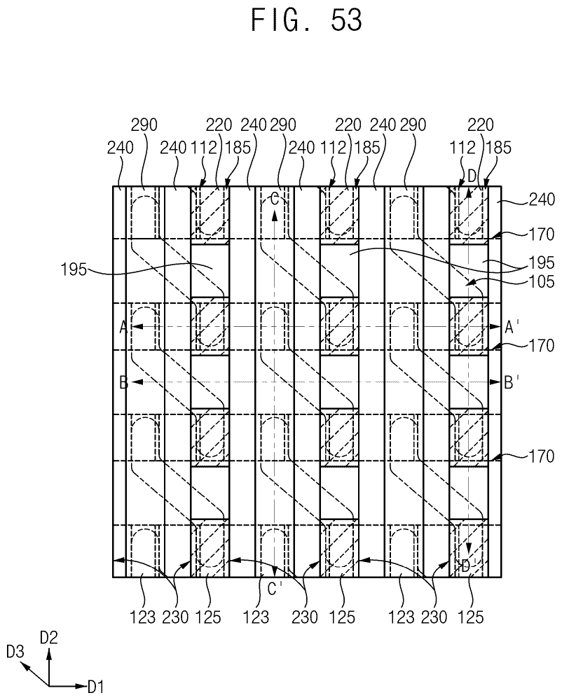

Referring to FIGS. 53 to 55, an etching process may be performed to remove portions of the first contact plug layer 180 and the buffer layer structure overlapping the gate structure 170 in the vertical direction to form an eighth opening exposing the upper surface of the gate structure.

By the etching process, a plurality of eighth openings spaced apart from each other in the second direction D2 between the first bit line structures adjacent to each other in the first direction D1 may be formed. Accordingly, the first contact plug layer 180 may be divided into the plurality of the first contact plugs 185 spaced apart from each other in the second direction D2.

The second fence pattern 195 may be formed within the eighth opening. The second fence pattern 195 may be formed by, for example, forming the second fence layer 190 to a sufficient height to fill the eighth opening, and performing planarization process on the upper portion of the second fence layer 190 until the upper surfaces of the second buffer layer 220, the first spacer 240 and the first bit line 290 are exposed.

Thereafter, manufacturing of the semiconductor device may be completed by performing processes substantially the same as or similar to the processes illustrated with reference to FIGS. 31 to 35 and FIGS. 1 to 3.

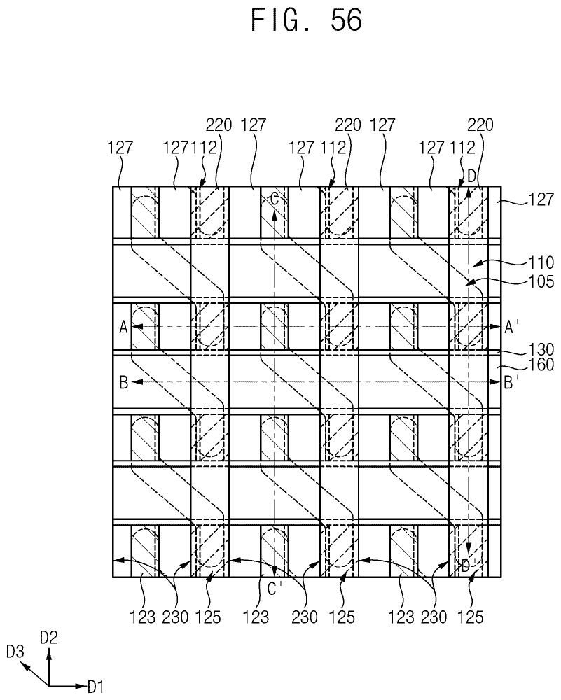

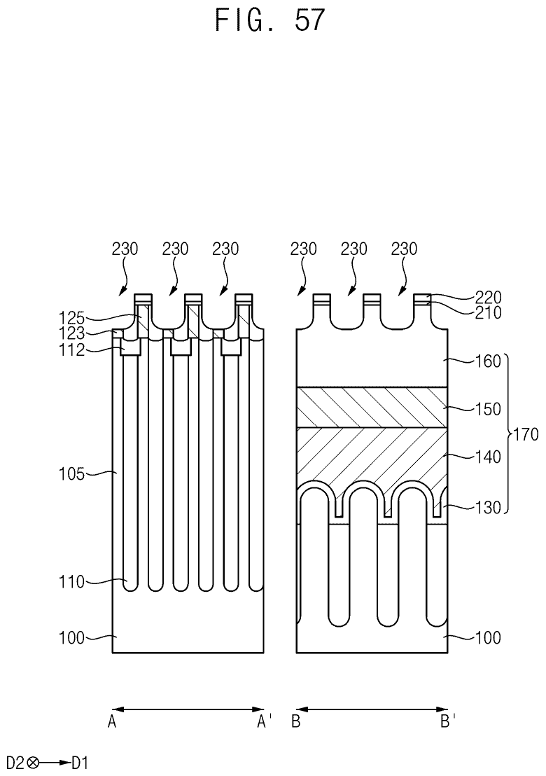

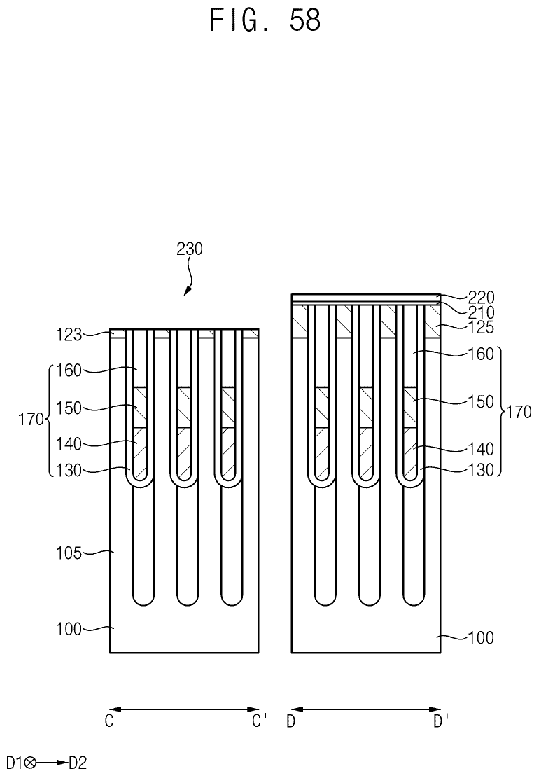

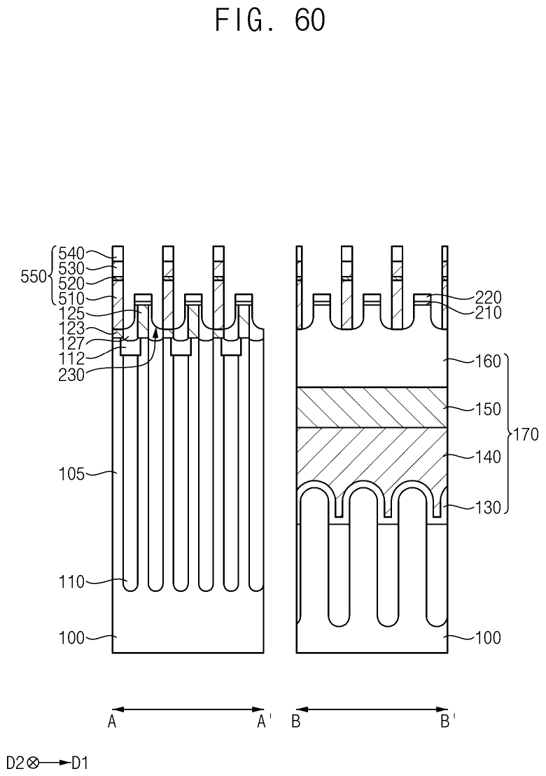

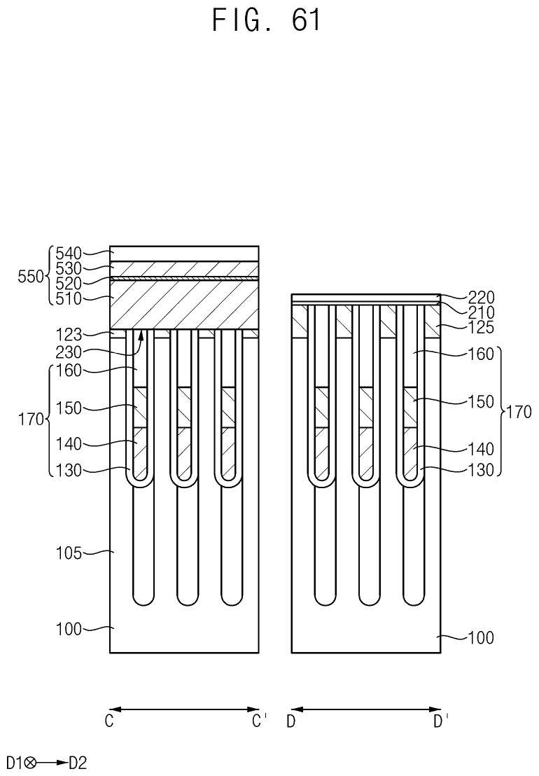

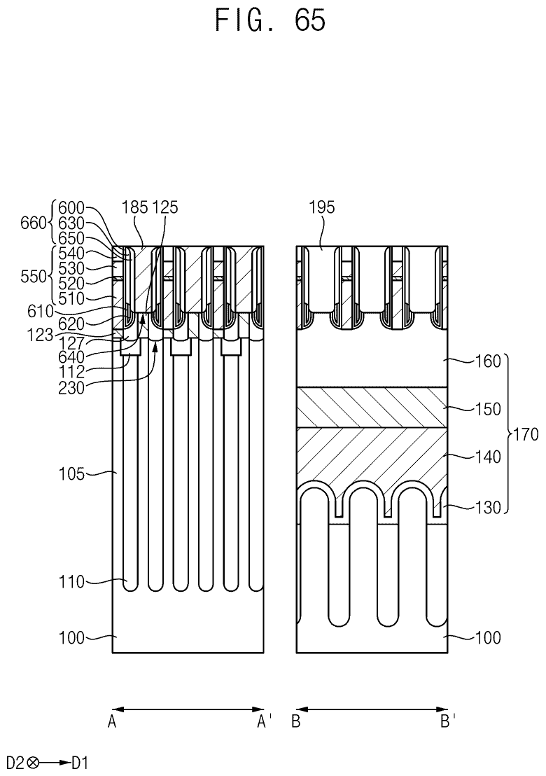

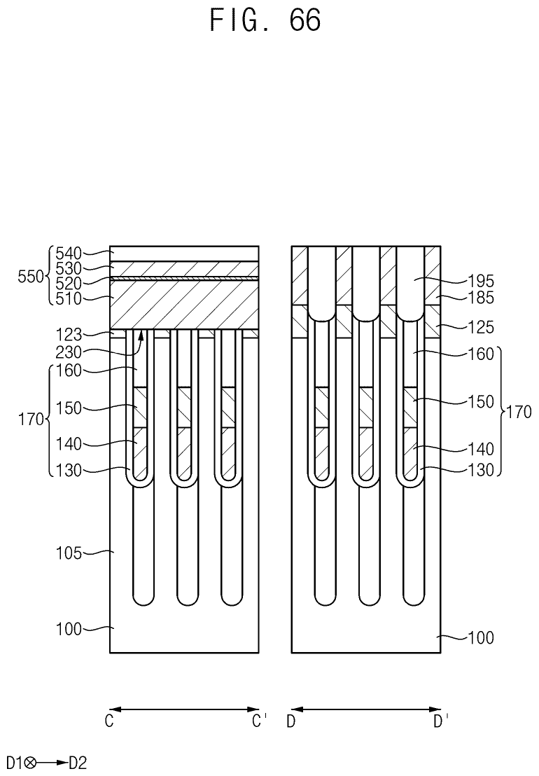

FIGS. 56 to 66 are plan views and cross-sectional views illustrating a method of forming a semiconductor device in accordance with example embodiments. Specifically, FIGS. 56, 59 and 64 are the plan view, FIGS. 57, 60, 62 and 65 include cross-sectional views taken along lines A-A′ and B-B′ of corresponding plan views, and FIGS. 58, 61, 63 and 66 include cross-sectional views taken along lines C-C′ and D-D′ of corresponding plan views.

This method may include processes substantially the same as or similar to those illustrated with reference to FIGS. 1 to 35, except for processes of forming of the first contact plug 185, the second fence pattern 195 and the second bit line 550 formed instead of the first bit line 290 illustrated with reference to FIGS. 22 to 30, and thus repeated explanations thereof are omitted herein.

Referring to FIGS. 56 to 58, after performing processes substantially the same as or similar to those illustrated with reference to FIGS. 4 to 21, the buffer layer structure may be formed on the first and second pad patterns 123 and 125 and the first fence pattern 127. The buffer layer structure may include the first buffer layer 210 and the second buffer layer 220 sequentially stacked in the vertical direction.

An etching process may be performed to form the second opening 230 extending through or extending into the buffer layer structure, the gate structure 170, the first pad pattern 123 and the first fence pattern 127. The second opening 230 may expose the upper surfaces of the first pad patterns 123 of the first pad pattern column and the gate structures 170 adjacent thereto in the second direction D2.

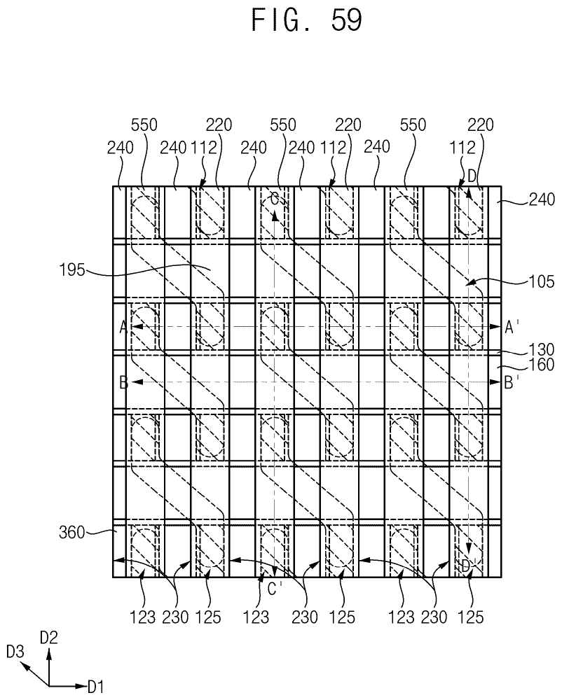

Referring to FIGS. 59 to 61, a fourth conductive layer, a barrier layer, a fifth conductive layer and a second bit line mask layer may be sequentially formed on the second buffer layer 220 and the first pad pattern 123, the first fence pattern 127 and the gate structure 170 exposed by the second opening 230. Thereafter, the second bit line mask layer, the fifth conductive layer, the barrier layer and the fourth conductive layer may be sequentially etched.

A fourth conductive pattern 510, a barrier pattern 520, a fifth conductive pattern 530 and a second bit line mask 540 sequentially stacked may be formed on the bottom of the second opening by the etching process.

The fourth conductive pattern 510, the barrier pattern 520, the fifth conductive pattern 530 and the second bit line mask 540 sequentially stacked may form the second bit line 550 together. In example embodiments, the second bit line 550 may extend in the second direction D2 on the substrate 100, and a plurality of second bit lines 550 may be spaced apart from each other in the first direction D1.

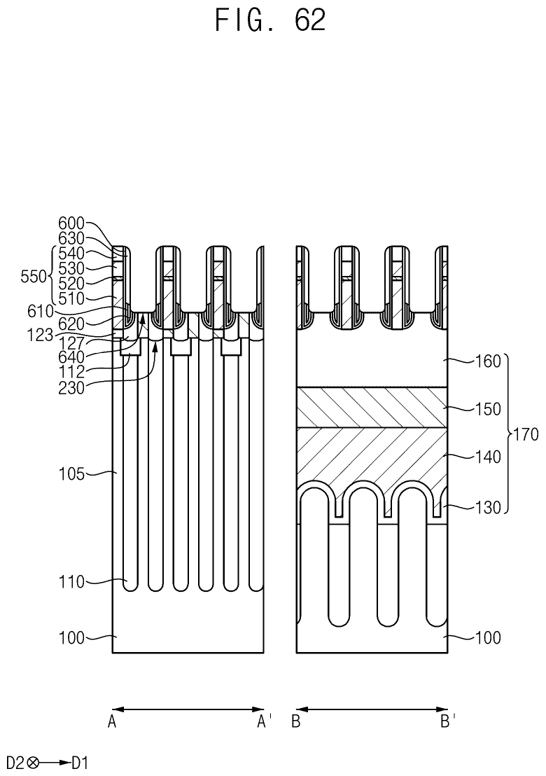

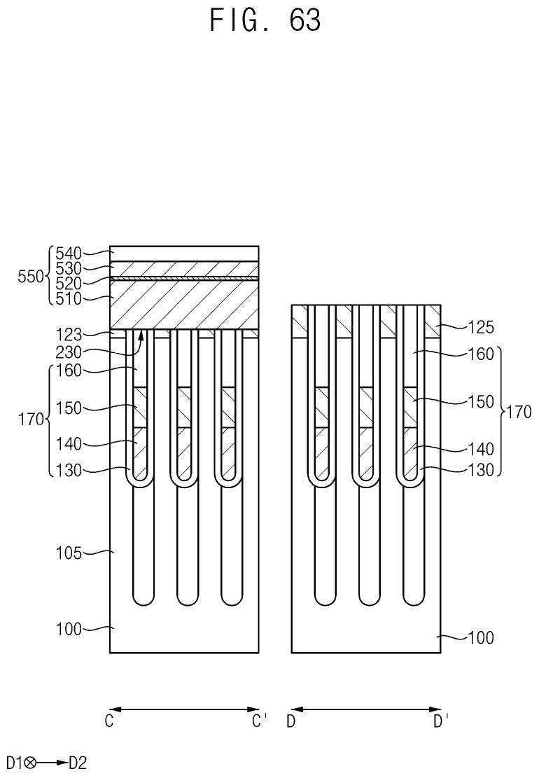

Referring to FIGS. 62 and 63, a third spacer layer may be formed on the substrate 100 on which the second bit line 550 is formed, and second and third insulating layers may be sequentially formed on the third spacer layer. The second and third insulating layers may fill a remaining portion of the second opening 230.

The second and third insulating layers may be etched by an etching process. Portions of the second and third insulating layers except for portions thereof in the second opening 230 may be removed. Accordingly, most portions of a surface of the third spacer layer, that is, all portions of the surface of the third spacer layer except for a portion of the surface thereof in the second opening 230 may be exposed, and the second and third insulating layers remaining in the second opening 230 may form second and third insulation patterns 610 and 620, respectively.

A fourth spacer layer may be formed on the exposed surface of the third spacer layer and the second and third insulation patterns 610 and 620 in the second opening 230. The fourth spacer layer may be anisotropically etched to form a fourth spacer 630 covering or overlapping a sidewall of the second bit line 550 on the surface of the third spacer layer and on the second and third insulation patterns 610 and 620.

An etching process using the second bit line mask 540 and the fourth spacer 630 as an etching mask may be performed to form a ninth opening 640 exposing the upper surface of the second pad pattern 125. In example embodiments, the ninth opening 640 may extend in the second direction D2 and a plurality of ninth openings 640 may be spaced apart from each other in the first direction D1. Accordingly, the ninth opening 640 may expose the upper surfaces of the second pad patterns 125 of the second pad pattern column and the upper surfaces of the gate structures 170 adjacent thereto in the second direction D2.

In example embodiments, the upper surfaces of the first fence patterns 127 adjacent to the second pad pattern 125 in the first direction D1 may also be exposed by the ninth opening 640.

By the etching process, a portion of the third spacer layer on the upper surface of the second bit line mask 540 and the upper surface of the second buffer layer 220 may be removed, thereby forming a third spacer 600 covering or overlapping a sidewall of the second bit line 550.

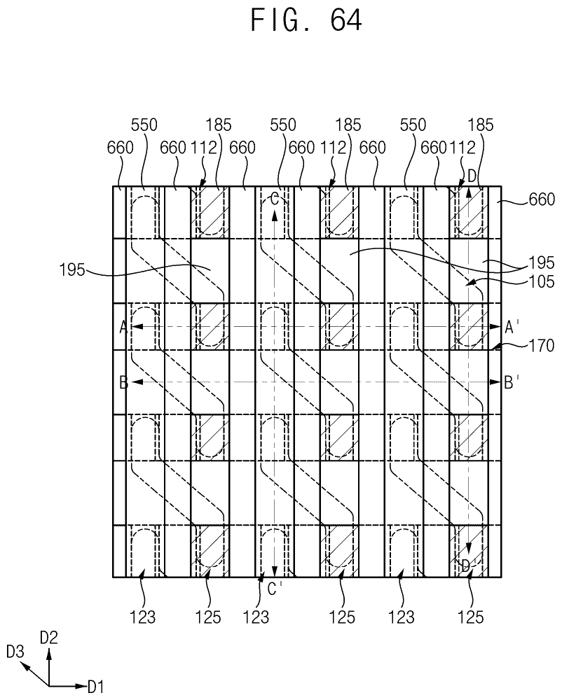

Referring to FIGS. 64 to 66, a fifth spacer layer may be formed on an upper surface of the second bit line mask 540, an outer sidewall of the fourth spacer 630, portions of the upper surfaces of the second and third insulation patterns 610 and 620 and upper surfaces of the second pad patterns 125 exposed by the ninth opening. The fifth spacer layer may be anisotropically etched to form a fifth spacer 650 covering or overlapping the sidewall of the second bit line 550.

The third to fifth spacers 600, 630 and 650 sequentially stacked on the sidewall of the second bit line 550 in the horizontal direction may be referred to as a spacer structure 660.

Referring to FIGS. 64 to 66, the first contact plug layer 180 may be formed to fill the ninth opening 640 to a sufficient height, and an upper portion of the first contact plug layer 180 may be planarized until the upper surface of the second bit line mask 540 is exposed. Accordingly, the first contact plug layer 180 may extend in the second direction D2 and a plurality of first contact plug layers 180 may be spaced apart from each other by the second bit lines 550 in the first direction D1.

An etching process may be performed on the first contact plug layer 180 to form a tenth opening exposing the upper surface of the gate structure 170. Accordingly, the first contact plug layer 180 may be transformed into a plurality of first contact plugs 185 spaced apart from each other in the second direction D2. The first contact plugs 185 may be formed on the second pad patterns 125, respectively. In example embodiments, the first contact plugs 185 may be spaced apart from each other in the first and second directions D1 and D2.

The second fence layer 190 may be formed to a sufficient height in the tenth opening, and an upper portion of the second fence layer may be planarized until the upper surface of the first contact plug 185 is exposed. Accordingly, the second fence pattern 195 may be formed within each of the tenth openings.

In example embodiments, the second fence pattern 195 may overlap in the vertical direction a portion of the gate structure 170 between the first contact plugs 185 adjacent to each other in the second direction D2. In example embodiments, the second fence patterns 195 may be spaced apart from each other in the first and second directions D1 and D2.

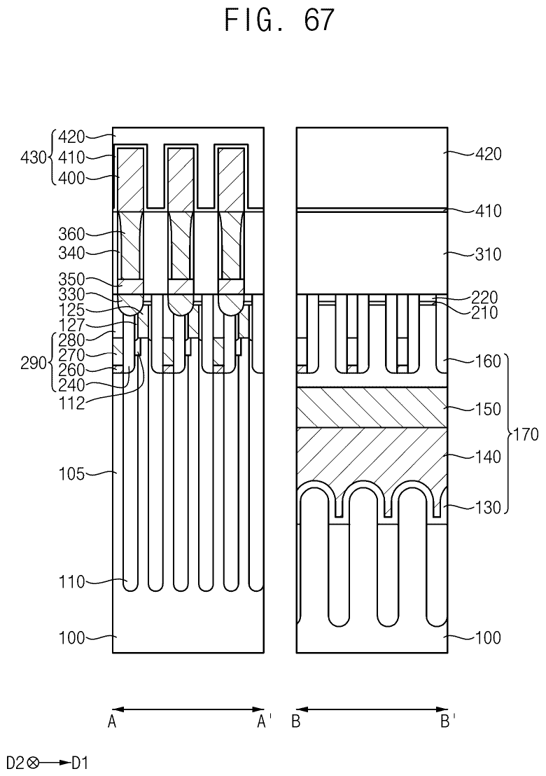

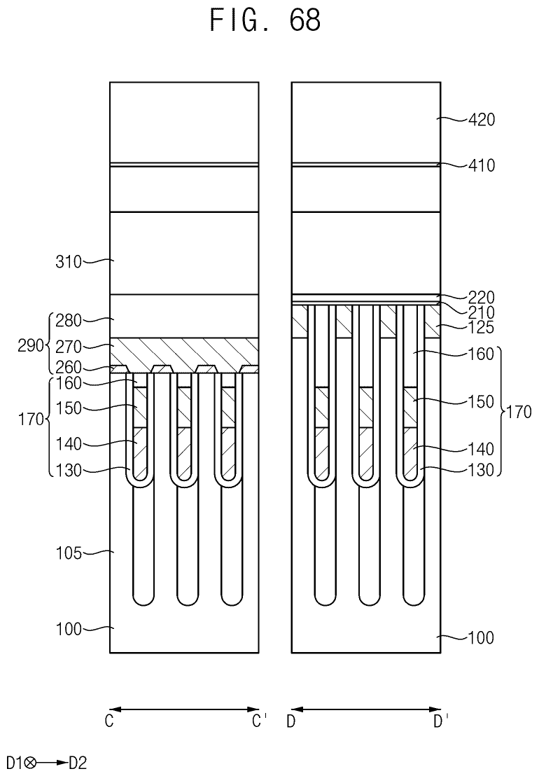

FIGS. 67 and 68 are cross-sectional views illustrating a semiconductor device in accordance with example embodiments. The semiconductor device may be substantially the same as or similar that of FIGS. 1 to 3, except for not including the first pad patterns 123, the first contact plug 185 and the second fence pattern 195, and thus, repeated explanations are omitted herein.

Referring to FIGS. 67 and 68, the first bit line structure may extend through or extend into upper portions of the first end portions of the active patterns 105 of the active pattern column, the first insulation pattern 112 and the isolation pattern 110. Accordingly, a lower surface of the first bit line structure may be lower than the upper surface of the second pad pattern 125.

The second contact plug 330 may be formed in the third opening 320 extending through or extending into the first bit line mask 280, the first spacer 240, the buffer layer structure, the first fence pattern 127 and/or the second pad pattern 125. Accordingly, the second contact plug 330 may directly contact the second pad pattern 125.

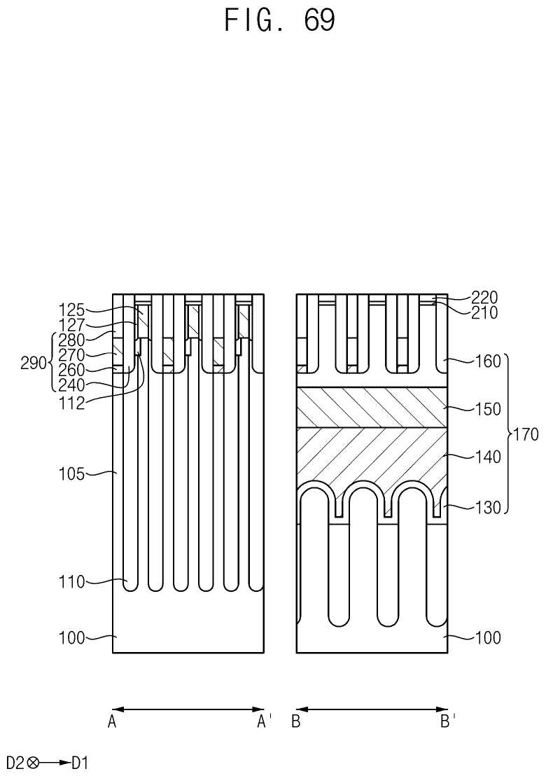

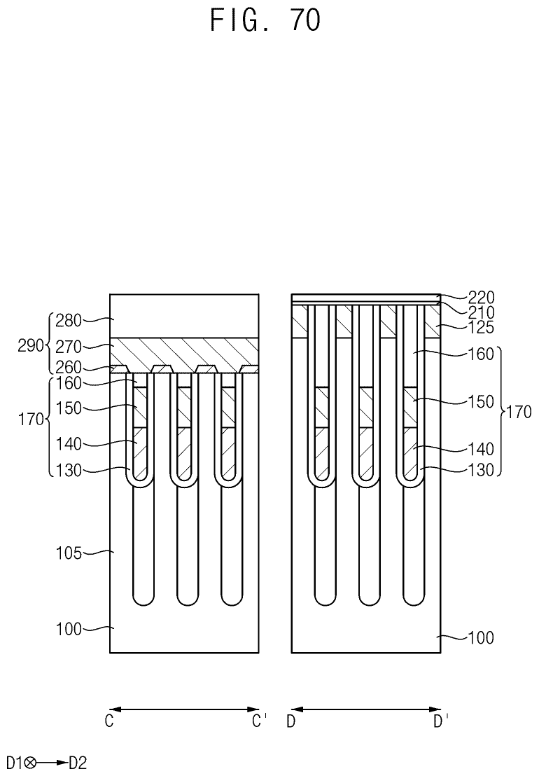

FIGS. 69 and 70 are cross-sectional views illustrating a method of forming a semiconductor device illustrated with reference to FIGS. 67 and 68. Specifically, FIG. 69 includes cross-sectional views taken along lines A-A′ and B-B′ of a corresponding plan view, and FIG. 70 includes cross-sectional views taken along lines C-C′ and D-D′ of a corresponding plan view.

This method may include processes substantially the same as or similar to those illustrated with reference to FIGS. 1 to 35, except that processes illustrated with reference to FIGS. 22 to 24 are not performed, and thus repeated explanations thereof are omitted herein.

Referring to FIGS. 69 and 70, unlike the processes illustrated with reference to FIGS. 25 to 27, the buffer layer structure may be formed on the first and second pad patterns 123 and 125, the first fence pattern 127 and the gate structure 170. The buffer layer structure may include the first and second buffer layers 210 and 220 sequentially stacked in the vertical direction.

By performing an etching process, the second opening 230 extending through or extending into the buffer layer structure, the first pad pattern 123, the first fence pattern 127 and the first insulation pattern 112 may be formed to expose the first end portions of the active patterns 105 of the active pattern column.

During the etching process, the first pad patterns 123 may be removed, and the upper surface of the first end portion of the active pattern 105 may be formed to be lower than the upper surface of the second end portion of the active pattern 105.

Thereafter, manufacturing of the semiconductor device may be completed by performing processes substantially the same as or similar to the processes illustrated with reference to FIGS. 28 to 35 and FIGS. 1 to 3.

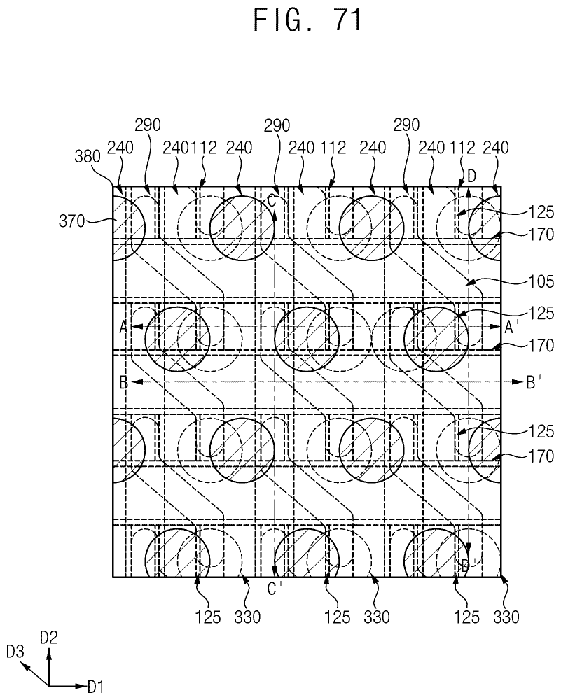

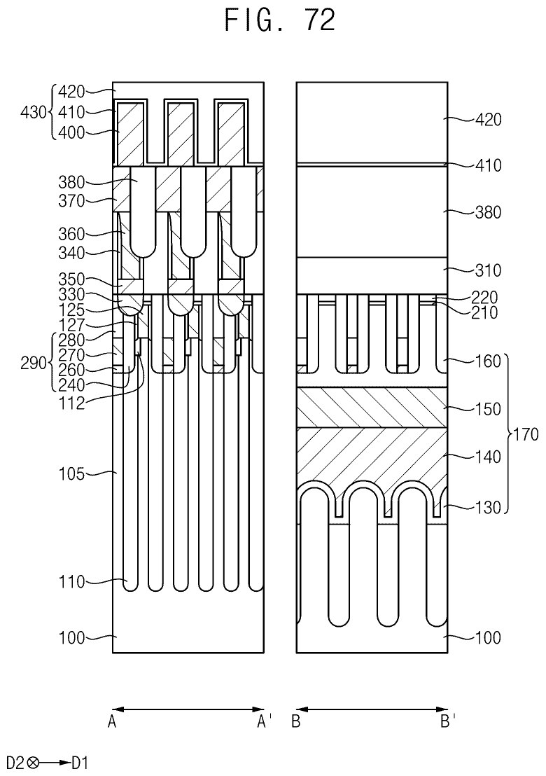

FIGS. 71 and 72 are a plan view and a cross-sectional view illustrating a semiconductor device in accordance with example embodiments. The semiconductor device may be substantially the same as or similar that of FIGS. 67 and 68, except for arrangement of the contact plug structure and further including a fourth contact plug 370 and a fourth insulation pattern 380, and thus, repeated explanations are omitted herein.

Meanwhile, in FIG. 71, the capacitor 430 is not shown to avoid complexity.

Referring to FIGS. 71 and 72, the contact plug structures may be arranged, for example, in a lattice pattern in a plan view.

The fourth contact plug 370 may be formed on the contact plug structure. The fourth contact plug 370 may be arranged, for example, in a honeycomb pattern in a plan view. In example embodiments, the fourth contact plug 370 may include, for example, a metal pattern including, for example, a metal, and a barrier pattern covering or overlapping a lower surface of the metal pattern and including, for example, a metal nitride.

The fourth insulation pattern 380 may partially or fully fill a space between the fourth contact plugs 370. The fourth insulation pattern 380 may include, for example, a low dielectric material such as silicon oxide, silicon oxycarbide, silicon nitride, silicon oxycarbonitride, etc.

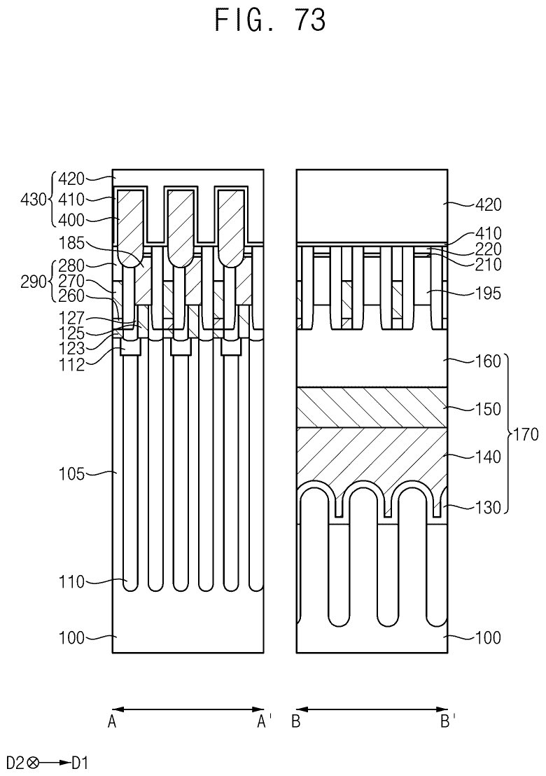

FIG. 73 is a cross-sectional view illustrating a semiconductor device in accordance with example embodiments. The semiconductor device may be substantially the same as or similar that of FIGS. 1 to 3, except for not including the second mold layer 310, the second contact plug 330, the second spacer 340, the second ohmic contact pattern 350 and the third contact plug 360, and the shape of the lower electrode 400, and thus, repeated explanations are omitted herein.

Referring to FIG. 73, the lower electrode 400 may extend through or extend into the buffer layer structure, an upper portion of the first spacer 240 and an upper portion of the first bit line mask 280 to directly contact the first contact plug 185.

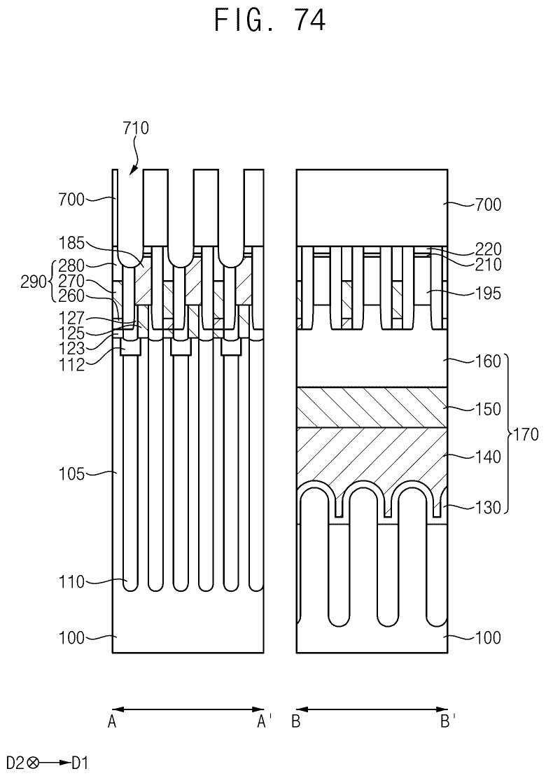

FIG. 74 is a cross-sectional view illustrating a method of forming a semiconductor device illustrated with reference to FIG. 73. Specifically, FIG. 74 is a cross-sectional view taken along line A-A′ of a corresponding plan view.

This method may include processes substantially the same as or similar to those illustrated with reference to FIGS. 1 to 35, except that processes illustrated with reference to FIGS. 31 to 35 are not performed, and thus repeated explanations thereof are omitted herein.

Referring to FIG. 74, processes substantially the same as or similar to those described with reference to FIGS. 4 to 30 may be performed. Thereafter, unlike the processes illustrated with reference to FIGS. 1 to 3, the fifth mold layer 700 may be formed on the second buffer layer 220, the first bit line 290 and the first spacer 240.

An eleventh opening 710 extending through or extending into the first and second buffer layers 210 and 220 and upper portions of the first spacer 240, the first bit line mask 280 and the first contact plug 185 may be formed, and the lower electrode 400 may be formed within the eleventh opening 710. Accordingly, the lower electrode 400 may directly contact the first contact plug 185.

While example embodiments have been particularly shown and described, it will be understood by one of ordinary skill in the art that variations in form and detail may be made therein without departing from the spirit and scope of the claims.

What is claimed is:

1. A semiconductor device comprising:
an active pattern on a substrate, the active pattern including a central portion, and a first end portion and a second end portion at opposite ends of the central portion;
an insulation pattern that extends into a portion of the first end portion of the active pattern and extends into a portion of the second end portion of the active pattern;
a first pad pattern and a second pad pattern respectively on the first and second end portions of the active pattern;
a gate structure that extends into the central portion of the active pattern;
a bit line structure on the first pad pattern;
a contact plug structure on the second pad pattern; and
a capacitor on the contact plug structure,
wherein an area of an upper surface of the first pad pattern is greater than an area of an upper surface of the first end portion of the active pattern directly contacting the first pad pattern, and an area of an upper surface of the second pad pattern is greater than an area of an upper surface of the second end portion of the active pattern directly contacting the second pad pattern.

2. The semiconductor device of claim 1, wherein the gate structure extends in a first direction, the bit line structure extends in a second direction,
wherein the first and second directions are substantially parallel to an upper surface of the substrate and are substantially perpendicular to each other,
wherein the central portion of the active pattern extends in a third direction, and the first and second end portions of the active pattern extend in the second direction away from the central portion of the active pattern, respectively, and
wherein the third direction has an acute angle with respect to the second direction and an obtuse angle with respect to the first direction.

3. The semiconductor device of claim 2, wherein the portion of the first end portion of the active pattern that the insulation pattern extends into is a first end in the first direction of the first end portion of the active pattern, and the portion of the second end portion of the active pattern that the insulation pattern extends into is a second end in the first direction of the second end portion of the active pattern.

4. The semiconductor device of claim 1, wherein each of the first and second pad patterns includes silicon.

5. The semiconductor device of claim 1, wherein ones of a plurality of active patterns including the active pattern are spaced apart from each other in a first direction and a second direction,
wherein the first direction and the second direction are substantially parallel to an upper surface of the substrate and are substantially perpendicular to each other, and
wherein first ones of the plurality of active patterns arranged in the first direction comprise an active pattern row, and second ones of the plurality of active patterns arranged in the second direction comprise an active pattern column.

6. The semiconductor device of claim 5, wherein respective first end portions of the active patterns of the active pattern row are arranged on a straight line extending in the first direction, and respective second end portions of the active patterns of the active pattern row are arranged on a straight line extending in the first direction, and
wherein respective first end portions of the active patterns of the active pattern column are arranged on a straight line extending in the second direction, and respective second end portions of the active patterns of the active pattern column are arranged on a straight line extending in the second direction.

7. The semiconductor device of claim 6, wherein ones of a plurality of active pattern rows including the active pattern row are spaced apart from each other in the second direction, and the respective first end portions of the active patterns of a first active pattern row of the active pattern rows and the respective second end portions of the active patterns of a second active pattern row of the active pattern rows are alternatively and repeatedly arranged in the first direction, and
wherein the first and second active pattern rows are adjacent to each other in the second direction.

8. A semiconductor device comprising:
active patterns on a substrate, the active patterns including respective central portions, respective first end portions, and respective second end portions, the respective first end portions and the respective second end portions at opposite ends of the respective central portions, wherein the active patterns are spaced apart from each other in a first direction and in a second direction, and wherein the first direction and the second direction are substantially parallel to an upper surface of the substrate and are substantially perpendicular to each other;
insulation patterns that extend into respective portions of ones of the respective first end portions of first active patterns of the active patterns, and respective portions of ones of the respective second end portions of second active patterns of the active patterns, wherein respective ones of the first and second active patterns are adjacent to each other in the first direction;
first pad patterns respectively on the respective first end portions of the active patterns;
second pad patterns respectively on the respective second end portions of the active patterns;
gate structures that each extend into the respective central portions of the active patterns in the first direction, wherein the gate structures are spaced apart from each other in the second direction;
bit line structures that extend in the second direction on the first pad patterns, wherein the bit line structures are spaced apart from each other in the first direction;
contact plug structures respectively on the second pad patterns; and
capacitors respectively on the contact plug structures.

9. The semiconductor device of claim 8, wherein the respective central portions of the active patterns extend in a third direction that has an acute angle with respect to the second direction and an obtuse angle with respect to the first direction.

10. The semiconductor device of claim 8, wherein each of the first pad patterns and the second pad patterns includes silicon.

11. The semiconductor device of claim 8, wherein the active patterns arranged in the first direction comprise an active pattern row, and ones of a plurality of active pattern rows including the active pattern row are spaced apart from each other in the second direction, and
wherein the respective first end portions of the active patterns of a first active pattern row of the active pattern rows and the respective second end portions of the active patterns of a second active pattern row of the active pattern rows are alternatively and repeatedly arranged in the first direction, and
wherein the first and second active pattern rows are adjacent to each other in the second direction.

12. The semiconductor device of claim 11, wherein the first pad patterns and the second pad patterns are alternately and repeatedly arranged in the first direction, corresponding to the respective first and second end portions of the active patterns.

13. The semiconductor device of claim 12, further comprising:
a fence pattern between the first and second pad patterns that are adjacent to each other in the first direction.

14. The semiconductor device of claim 13, wherein lower surfaces of the first and second pad patterns are a closer to the substrate than a lower surface of the fence pattern.

15. The semiconductor device of claim 13, wherein lower surfaces of the first and second pad patterns are further away the substrate than a lower surface of the fence pattern

16. The semiconductor device of claim 8, wherein each of the first and second pad patterns overlaps respective ones of the insulation patterns in a vertical direction substantially perpendicular to the upper surface of the substrate.

17. A semiconductor device comprising:
an active pattern on a substrate, the active pattern including a central portion, and a first end portion and a second end portion that are at opposite ends of the central portion;
an insulation pattern that extends into a portion of the first end portion of the active pattern and extends into a portion of the second end portion of the active pattern;
a first pad pattern and a second pad pattern respectively on the first and second end portions of the active pattern;
a gate structure that extends into the central portion of the active pattern;
a bit line structure on the first pad pattern;
a contact plug structure on the second pad pattern; and
a capacitor on the contact plug structure,
wherein an uppermost surface of the insulation pattern with respect to the substrate and an upper surface of the second pad pattern with respect to the substrate are substantially coplanar.

18. The semiconductor device of claim 17, wherein the gate structure extends in a first direction, the bit line structure extends in a second direction,
wherein the first direction and the second direction are substantially parallel to an upper surface of the substrate and are substantially perpendicular to each other, and
wherein the central portion of the active pattern extends in a third direction, and the first and second end portions of the active pattern extend in the second direction away from the central portion of the active pattern, and
wherein the third direction has an acute angle with respect to the second direction and an obtuse angle with respect to the first direction.

19. The semiconductor device of claim 18, wherein the portion of the first end portion of the active pattern that the insulation pattern extends into is a first end in the first direction of the first end portion of the active pattern, and the portion of the second end portion of the active pattern that the insulation pattern extends into is a second end in the first direction of the second end portion of the active pattern.

20. The semiconductor device of claim 17, wherein each of the first and second pad patterns includes silicon.
